(19) United States
(12) Patent Application Publication
(10) Pub. No.: US 2025/0331385 A1
(43) Pub. Date: Oct. 23, 2025

(54) DISPLAY SUBSTRATE, DISPLAY PANEL, AND PHOTOMASK SET

(71) Applicants: Chengdu BOE Optoelectronics Technology Co., Ltd., Chengdu, Sichuan (CN); BOE Technology Group Co., Ltd., Beijing (CN)

(72) Inventors: Kui Wang, Beijing (CN); Xinxing Guan, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/992,277

(22) PCT Filed: Apr. 17, 2024
(86) PCT No.: PCT/CN2024/088444

§ 371 Date: Jan. 8, 2025

(30) Foreign Application Priority Data
May 25, 2023 (CN) 202310605353.3

(51) Int. Cl. H10K 59/35; C23C 14/04; H10K 59/12; H10K 59/131; H10K 71/16

(52) U.S. Cl. CPC H10K 59/353; C23C 14/042; H10K 59/1201; H10K 59/131; H10K 59/352; H10K 71/166

(57) ABSTRACT

In a displaying base board, each pixel unit includes three sub-pixels. The centers of the first sub-pixel, the second sub-pixel and the third sub-pixel are sequentially located at the vertex positions of a virtual triangle. The connecting line between the center of the first sub-pixel and the center of any one of the other sub-pixels in the same one pixel unit has an included angle with at least one of a first direction and a second direction, which are the directions of extension of the same one queue of the first sub-pixels and intersect. Both of more than a half of the region of the second sub-pixel and at least a half of the region of the third sub-pixel in the same one pixel unit are located on the same one side of the connecting line of the centers of the same one queue of the first sub-pixels.

### CROSS REFERENCE TO RELEVANT APPLICATIONS

The present application claims the priority of the Chinese patent application filed on May 25, 2023 before the Chinese Patent Office with the application number of 202310605353.3 and the title of “DISPLAY SUBSTRATE, DISPLAY PANEL, AND PHOTOMASK SET”, which is incorporated herein in its entirety by reference.

### TECHNICAL FIELD

The present application relates to the technical field of displaying, and particularly relates to a displaying base board, a display panel and a mask group.

### BACKGROUND

The OLED (Organic Light Emitting Diode) displaying technique, because of its advantages such as low weight and size, self-illumination, a wide visual angle, a high response speed, a low brightness and a low power consumption, is commonly recognized as a third-generation displaying technique by the industry, and has become the main development trend of the technical field of displaying. Currently, in the fields such as mobile phones, wearable devices and onboard displaying, OLED displaying devices have already begun replacing the traditional liquid crystal display screen (Liquid Crystal Display, LCD).

### SUMMARY

The embodiments of the present application employ the following technical solutions:

In the first aspect, an embodiment of the present application provides a displaying base board, wherein the displaying base board comprises a substrate and a plurality of pixel units that are located on the substrate and are arranged in an array, and each of at least some of the pixel units comprises a first sub-pixel, a second sub-pixel and a third sub-pixel;
a center of the first sub-pixel, a center of the second sub-pixel and a center of the third sub-pixel are sequentially located at vertex positions of a virtual triangle;
a connecting line between the center of the first sub-pixel and the center of any one of the other sub-pixels in a same one instance of the pixel units has an included angle with at least one of a first direction and a second direction, wherein each of the first direction and the second direction is a direction of extension of a same one queue of the first sub-pixels, and the first direction and the second direction intersect; and
both of more than a half of a region of the second sub-pixel and at least a half of a region of the third sub-pixel in a same one instance of the pixel units are located on a same one side of a connecting line of the centers of a same one queue of the first sub-pixels.

In at least one embodiment of the present application, the connecting line between the center of the first sub-pixel and the center of the any one of the other sub-pixels in the same one pixel unit has included angles with both of the first direction and the second direction.

In at least one embodiment of the present application, the connecting line between the center of the first sub-pixel and the center of the second sub-pixel in the same one pixel unit has an included angle with the first direction, wherein the first direction is a direction of extension of a same one column of the first sub-pixels.

In at least one embodiment of the present application, four instances of the first sub-pixels are located at vertex positions of a first virtual tetragon, the virtual triangle is located within the first virtual tetragon, and the first virtual tetragon and the virtual triangle share one vertex.

In at least one embodiment of the present application, in a same one instance of the pixel units, at least two of a distance between the center of the first sub-pixel and the center of the second sub-pixel, a distance between the center of the first sub-pixel and the center of the third sub-pixel, and a distance between the center of the second sub-pixel and the center of the third sub-pixel are substantially equal.

In at least one embodiment of the present application, the distance between the center of the first sub-pixel and the center of the second sub-pixel and the distance between the center of the first sub-pixel and the center of the third sub-pixel are substantially equal.

In at least one embodiment of the present application, the second direction is a direction of extension of a same one row of the first sub-pixels, the first virtual tetragon comprises a first lateral side extending in the first direction and a second lateral side extending in the second direction, the first lateral side and the second lateral side intersect at a first vertex, the first sub-pixel in the same one pixel unit is located at the first vertex, an orthographic projection of the second sub-pixel on the substrate and an orthographic projection of the first lateral side on the substrate at least partially do not overlap, and an orthographic projection of the third sub-pixel on the substrate and an orthographic projection of the second lateral side on the substrate partially overlap.

In at least one embodiment of the present application, in one instance of the first virtual tetragon, one instance of the pixel units exists in which an area of a region of the pixel unit that is located within the first virtual tetragon is greater than an area of a region of the pixel unit that is located outside the first virtual tetragon.

In at least one embodiment of the present application, the distance between the center of the first sub-pixel and the center of the second sub-pixel in the same one pixel unit is greater than a half of a side length of the first lateral side of the first virtual tetragon.

In at least one embodiment of the present application, the distance between the center of the first sub-pixel and the center of the third sub-pixel in the same one pixel unit is greater than a half of a side length of the second lateral side of the first virtual tetragon.

In at least one embodiment of the present application, in a same one instance of the pixel units, a minimum distance between an edge of the first sub-pixel and an edge of the second sub-pixel and a minimum distance between the edge of the first sub-pixel and an edge of the third sub-pixel are substantially equal.

In at least one embodiment of the present application, the minimum distance between the edge of the third sub-pixel and the edge of the first sub-pixel in the same one pixel unit is substantially equal to a minimum distance from the edge of the third sub-pixel to an edge of the first sub-pixel in a neighboring instance of the pixel units; and
the minimum distance between the edge of the second sub-pixel and the edge of the first sub-pixel in the same one pixel unit is substantially equal to a minimum distance from the edge of the second sub-pixel to the edge of the first sub-pixel in the neighboring pixel unit.

In at least one embodiment of the present application, the virtual triangle is an acute triangle, and the included angle between the connecting line between the center of the first sub-pixel and the center of the any one of the other sub-pixels in the same one pixel unit and the at least one of the first direction and the second direction is greater than 0° and less than or equal to 30°.

In at least one embodiment of the present application, an included angle between the connecting line between the center of the first sub-pixel and the center of the second sub-pixel in the same one pixel unit and a direction of extension of a same one column of the first sub-pixels is substantially equal to an included angle between the connecting line between the center of the first sub-pixel and the center of the third sub-pixel and a direction of extension of a same one row of the first sub-pixels.

In at least one embodiment of the present application, the first virtual tetragon is a rectangle, and an area of the virtual triangle is less than a half of an area of the first virtual tetragon.

In at least one embodiment of the present application, each of at least some of the pixel units further comprises a fourth sub-pixel, the first sub-pixel, the second sub-pixel, the third sub-pixel and the fourth sub-pixel are sequentially located at four vertex positions of a second virtual tetragon, the second virtual tetragon is located within the first virtual tetragon, and two lateral sides of the second virtual tetragon are shared with two lateral sides of the virtual triangle; and
the fourth sub-pixel is a light transmitting component, and an orthographic projection of the fourth sub-pixel on the substrate and an orthographic projection of at least one diagonal line of the first virtual tetragon on the substrate have an overlapping part.

In at least one embodiment of the present application, in a same one instance of the pixel units, a distance between a center of the fourth sub-pixel and the center of the second sub-pixel and a distance between the center of the fourth sub-pixel and the center of the third sub-pixel are substantially equal.

In at least one embodiment of the present application, in a same one instance of the pixel units, a minimum distance between an edge of the fourth sub-pixel and an edge of the second sub-pixel and a minimum distance between the edge of the fourth sub-pixel and an edge of the third sub-pixel are substantially equal.

In at least one embodiment of the present application, one instance of the fourth sub-pixel is located among four instances of the pixel units, the four pixel units are a first pixel unit, a second pixel unit, a third pixel unit and a fourth pixel unit, the first pixel unit and the second pixel unit are arranged in the first direction, and the first pixel unit and the fourth pixel unit are arranged in the second direction; and
for the fourth sub-pixel in the first pixel unit, a minimum distance from an edge of the fourth sub-pixel to an edge of the third sub-pixel in the second pixel unit, a minimum distance from the fourth sub-pixel to an edge of the first sub-pixel in the third pixel unit and a minimum distance from the fourth sub-pixel to an edge of the second sub-pixel in the fourth pixel unit are substantially equal.

In at least one embodiment of the present application, the first virtual tetragon comprises a first diagonal line and a second diagonal line, and the first vertex is located in the first diagonal line; and
at least a half of a region of the fourth sub-pixel is located on one side of the second diagonal line that is farther from the first vertex.

In at least one embodiment of the present application, the fourth sub-pixel is configured to expose a region where a light sensing device is provided, and the light sensing device is located on a shadow side of the displaying base board; and
the displaying base board comprises a trace layer located on the substrate, the trace layer comprises a plurality of traces, and orthographic projections of the traces on the substrate do not overlap with an orthographic projection of the fourth sub-pixel on the substrate.

In at least one embodiment of the present application, shapes of planar patterns of the first sub-pixel, the second sub-pixel, the third sub-pixel and the fourth sub-pixel are at least partially the same; and
each of the planar patterns of the first sub-pixel, the second sub-pixel, the third sub-pixel and the fourth sub-pixel comprises an are shape or a combination of an are shape and a polygon.

In the second aspect, an embodiment of the present application provides a display panel, wherein the display panel comprises the displaying base board according to any one of the embodiments in the first aspect.

In the third aspect, an embodiment of the present application provides a mask group, wherein the mask group is applied to fabricate the displaying base board according to any one of the embodiments in the first aspect;
the mask group comprises:
a first mask comprising a plurality of first openings, wherein the first openings are configured for forming luminescent layers of the first sub-pixels;
a second mask comprising a plurality of second openings, wherein the second openings are configured for forming luminescent layers of the second sub-pixels; and
a third mask comprising a plurality of third openings, wherein the third openings are configured for forming luminescent layers of the third sub-pixels;
the mask group comprises opening groups, and each of the opening groups comprises one instance of the first openings, one instance of the second openings and one instance of the third openings;
in a same one instance of the opening groups, connecting lines between an orthographic projection of an outer contour of the second opening on the first mask, an orthographic projection of an outer contour of the third opening on the first mask and a center of an outer contour of the first opening form an acute triangle; and
a connecting line between a center of the orthographic projection of the outer contour of the second opening on the first mask and the center of the outer contour of the first opening has an included angle with a net-deployment stretching direction of the masks.

In at least one embodiment of the present application, a connecting line between a center of the orthographic projection of the outer contour of the third opening on the first mask and the center of the outer contour of the first opening has an included angle with a vapor-deposition scanning direction.

In at least one embodiment of the present application, the orthographic projection of the outer contour of the second opening on the first mask and the orthographic projection of the outer contour of the third opening on the first mask are tangent to the outer contour of the first opening, and the orthographic projection of the outer contour of the second opening on the first mask and the orthographic projection of the outer contour of the third opening on the first mask are tangent to each other.

In at least one embodiment of the present application, the included angle between the connecting line between the center of the orthographic projection of the outer contour of the second opening on the first mask and the center of the outer contour of the first opening and the net-deployment stretching direction of the masks is greater than 0° and less than or equal to 30°.

In at least one embodiment of the present application, the included angle between the connecting line between the center of the orthographic projection of the outer contour of the third opening on the first mask and the center of the outer contour of the first opening and the vapor-deposition scanning direction is greater than 0° and less than or equal to 30°.

The above description is merely a summary of the technical solutions of the present application. In order to more clearly know the elements of the present application to enable the implementation according to the contents of the description, and in order to make the above and other purposes, features and advantages of the present application more apparent and understandable, the particular embodiments of the present application will be provided below.

### BRIEF DESCRIPTION OF THE DRAWINGS

In order to more clearly illustrate the technical solutions of the embodiments of the present application or the prior art, the figures that are required to describe the embodiments or the prior art will be briefly described below. Apparently, the figures that are described below are merely embodiments of the present application, and a person skilled in the art can obtain other figures according to these figures without paying creative work.

FIG. 1 is a diagram illustrating color mixing in the vapor-deposition process of a displaying base board in the related art;

FIG. 2 is a schematic planar structural diagram of a displaying base board in the related art;

FIGS. 3-16 are schematic planar structural diagrams of fourteen types of displaying base boards according to embodiments of the present application;

FIGS. 17-24 are schematic planar structural diagrams of eight types of displaying base boards having a light transmitting component according to embodiments of the present application;

FIG. 25 is a schematic cross-sectional structural diagram of a displaying base board having a light transmitting component according to an embodiment of the present application; and

FIGS. 26-29 are four schematic planar structural diagrams of the superposition between the mask group and the sub-pixels according to embodiments of the present application.

### DETAILED DESCRIPTION

The technical solutions of the embodiments of the present application will be clearly and completely described below with reference to the drawings of the embodiments of the present application. Apparently, the described embodiments are merely certain embodiments of the present application, rather than all of the embodiments. All of the other embodiments that a person skilled in the art obtains on the basis of the embodiments of the present application without paying creative work fall within the protection scope of the present application.

In the embodiments of the present application, terms such as “first”, “second”, “third” and “fourth” are used to distinguish identical items or similar items that have substantially the same functions and effects, merely in order to clearly describe the technical solutions of the embodiments of the present application, and should not be construed as indicating or implying the degrees of importance or implicitly indicating the quantity of the specified technical features.

In the embodiments of the present application, the terms that indicate orientation or position relations, such as “upper” and “lower”, are based on the orientation or position relations shown in the drawings, and are merely for conveniently describing the present application and simplifying the description, rather than indicating or implying that the device or element must have the specific orientation and be constructed and operated according to the specific orientation. Therefore, they should not be construed as a limitation on the present application.

In the description of the present application, the terms “one embodiment”, “some embodiments”, “exemplary embodiment”, “example”, “specific example” or “some examples” are intended to indicate that specific features, structures, materials or characteristics related to the embodiment or example are comprised in at least one embodiment or example of the present application. The illustrative indication of the above terms does not necessarily refer to the same one embodiment or example. Moreover, the specific features, structures, materials or characteristics may be comprised in any one or more embodiments or examples in any suitable manner.

In the embodiments of the present application, the meaning of “plurality of” is “two or more”, and the meaning of “at least one” is “one or more”, unless explicitly and particularly defined otherwise.

All of the features used in the embodiments of the present application of “substantially parallel”, “substantially perpendicular”, “substantially the same or substantially equal” and so on include the features of “parallel”, “perpendicular”, “the same or equal” and so on in the strict sense, and the cases in which there is a certain tolerance of “substantially parallel”, “substantially perpendicular”, “substantially the same or substantially equal” and so on, taking into consideration the measurement and the tolerances relevant to the measurement on particular quantities (for example, restricted by the measuring system), and represent that they are in the acceptable deviation ranges of the particular values determined by a person skilled in the art. For example, the “substantially” can represent that they are within one or more standard deviations, or within 3% or 5% of the values.

Unless stated otherwise in the context, throughout the description and the claims, the term “comprise” is interpreted as the meaning of opened containing, i.e., “including but not limited to”.

The polygons in the description are not the strictly defined polygons, may be an approximate triangle, parallelogram, trapezoid, pentagon, hexagon and so on, and may have some small deformations caused by rounded corners or tolerance.

The OLED (Organic Light Emitting Diode) displaying technique, because of its advantages such as low weight and size, self-illumination, a wide visual angle, a high response speed, a low brightness and a low power consumption, is commonly recognized as a third-generation displaying technique by the industry, and has become the main development trend of the technical field of displaying. Currently, in the fields such as mobile phones, wearable displaying and onboard displaying, OLED displaying devices have already begun replacing the traditional liquid-crystal display screen (Liquid Crystal Display, LCD).

The structure of an OLED displaying device mainly comprises a substrate base board and sub-pixels that are fabricated on the substrate base board and are arranged in a matrix. The sub-pixels are usually obtained by transmitting an organic material via a high-precision metal mask (FMM mask) by using a vapor-deposition film-formation technique, to form the organic electroluminescent structures at the corresponding sub-pixel positions of the array base board. If the sub-pixels occupy a higher proportion of the area, the device has a longer life. Therefore, various different pixel arrangement modes are proposed, to obtain a high pixel area proportion (i.e., the aperture ratio), for example, the pixel arrangement modes of Real RGB, GGRB, Diamond and Dealt. The four pixel arrangement modes may refer to the description in the related art, and are not discussed further herein. Among them, except the pixel arrangement mode of Real RGB, all of the other pixel arrangement modes realize a higher pixel density (Pixels Per Inch, PPI) by using the principle of sharing the sub-pixels, thereby realizing a higher resolution. However, that reduces the degree of the fineness of the displaying, and the displayed frame has sawteeth. Small-sized OLED displaying devices have a lower size, and thus have a stricter requirement on the fineness degree of the image displaying. Therefore, Real RGB is considered as the best solution for small-sized OLED displaying devices.

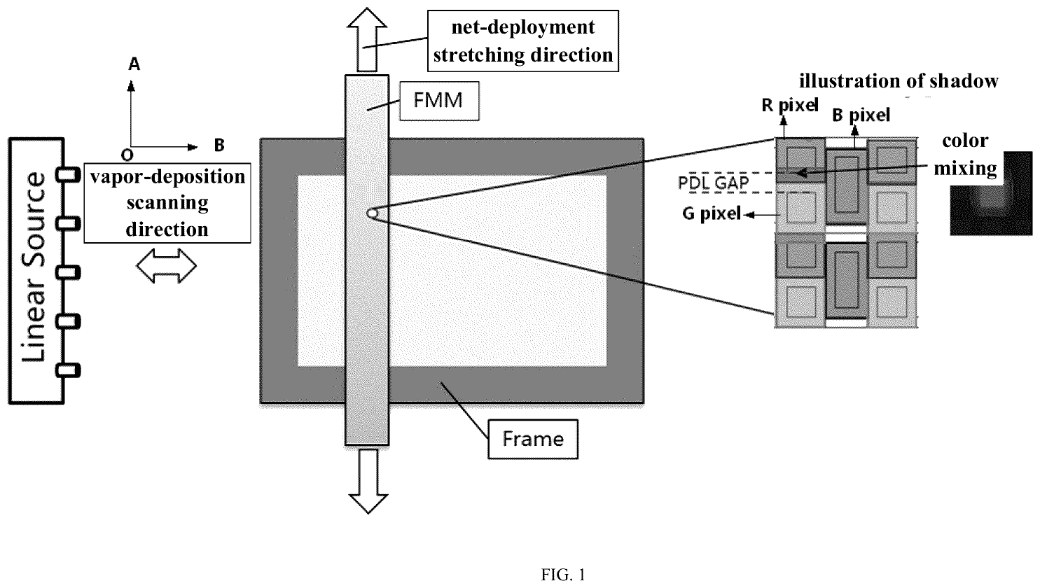

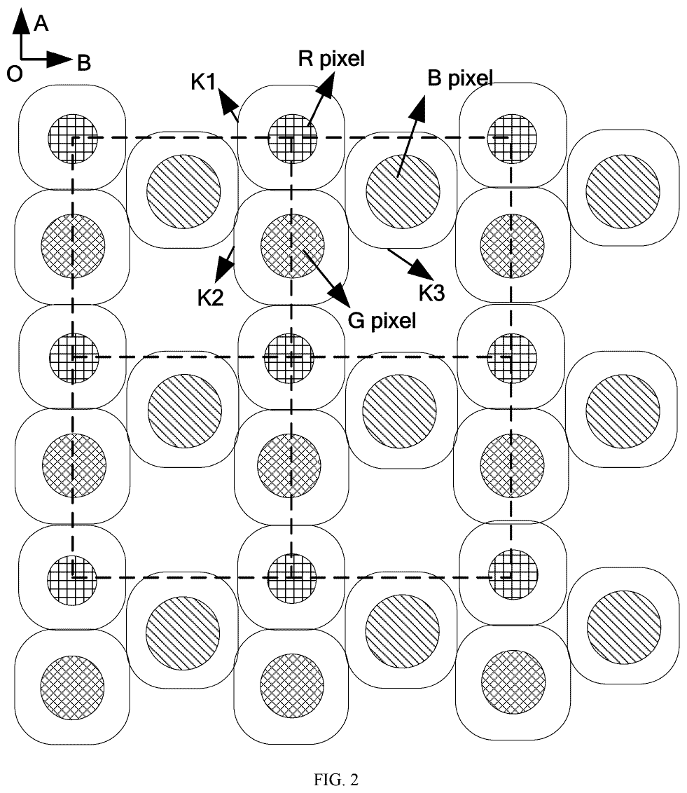

With the same resolution, as compared with the other pixel arrangement modes, the pixel arrangement mode of Real RGB has a better effect of displaying. However, the pixel arrangement mode of Real RGB has a lower aperture ratio, and the process difficulty is higher than those of the other pixel arrangement modes. As shown in FIG. 1, the mainstream OLED vapor-deposition mode is linear-source scanning, wherein the linear-source distribution direction (for example, the direction OA) is the same as the net-deployment stretching direction of the FMM mask (for example, the direction OA), and, at the same time, is the same as the direction of the minimum pixel spacing (PDL GAP) of Real RGB. As restricted by the influence by the vapor-deposition scanning direction of the linear source and the net-deployment direction of the FMM mask, the film-layer overlapping (Shadow) caused by the vapor deposition is increased preferentially in the linear-source distribution direction (for example, the direction OA). For example, in a displaying base board of the pixel arrangement mode of Real RGB, the luminescent layers of the red-color sub-pixel (R pixel) and the green-color sub-pixel (G pixel) might have an overlapping part therebetween, and, when the overlapping area therebetween is large and extends to the position of the pixel opening region, that results in color mixing, which deteriorates the effect of displaying. FIG. 2 provides a schematic structural diagram of a displaying base board in the related art, wherein the components labeled as K1, K2 and K3 are illustrations of the outer contours of the opening regions of the corresponding mask for fabricating the sub-pixels. In the related art shown in FIG. 2, color mixing easily happens between the luminescent layers of the red-color sub-pixel (R pixel) and the green-color sub-pixel (G pixel), which results in interference between light rays of different colors.

In view of the above, an embodiment of the present application provides a displaying base board, a display panel and a mask group. In the displaying base board, each of at least some of the pixel units comprises a first sub-pixel, a second sub-pixel and a third sub-pixel. The center of the first sub-pixel, the center of the second sub-pixel and the center of the third sub-pixel are sequentially located at the vertex positions of a virtual triangle. The connecting line between the center of the first sub-pixel and the center of any one of the other sub-pixels in the same one pixel unit has an included angle with at least one of a first direction and a second direction, wherein each of the first direction and the second direction is the direction of extension of the same one queue of the first sub-pixels, and the first direction and the second direction intersect. Both of more than a half of the region of the second sub-pixel and at least a half of the region of the third sub-pixel in the same one pixel unit are located on the same one side of the connecting line of the centers of the same one queue of the first sub-pixels. The connecting line between the center of the first sub-pixel and the center of any one of the other sub-pixels in the same one pixel unit has an included angle with at least one of the first direction and the second direction, and both of more than a half of the region of the second sub-pixel and at least a half of the region of the third sub-pixel in the same one pixel unit are located on the same one side of the connecting line of the centers of the same one queue of the first sub-pixels.

In the practical vapor-deposition process, when the linear-source distribution direction is the same as the first direction, and the linear-source vapor-deposition scanning direction is the same as the second direction, the connecting line between the center of the first sub-pixel and the center of the second sub-pixel (the third sub-pixel) has an included angle with at least one of a first direction and a second direction, and both of more than a half of the region of the second sub-pixel P2 and at least a half of the region of the third sub-pixel P3 in the same one pixel unit are located on the same one side of the connecting line of the centers of the same one queue of the first sub-pixels P1. Accordingly, in an aspect, the problem in the related art of the color mixing caused by the film-layer overlapping between two sub-pixels arranged in the linear-source distribution direction can be ameliorated, which improves the effect of displaying of the displaying base board to a large extent. In another aspect, while the sizes of the pixel openings of the sub-pixels are maintained constant, the spacing (Gap) between two neighboring sub-pixels can be increased, which further reduces the problem of the color mixing caused by the film-layer overlapping between two sub-pixels. In yet another aspect, while the spacing (Gap) between two neighboring sub-pixels is maintained constant, more design room can be used to increase the pixel openings (for example, increasing the areas of the anodes of the sub-pixels), thereby increasing the aperture ratio, to increase the light transmittance and the optical efficiency of the displaying base board. The evaporation source of the vapor-deposition chamber usually has three types: a point source, a linear source and a planar source, wherein the linear source refers to a vapor-deposition source distributed in a linear shape.

The displaying base board, the display panel and the mask group according to the embodiments of the present application will be described in detail below with reference to the drawings.

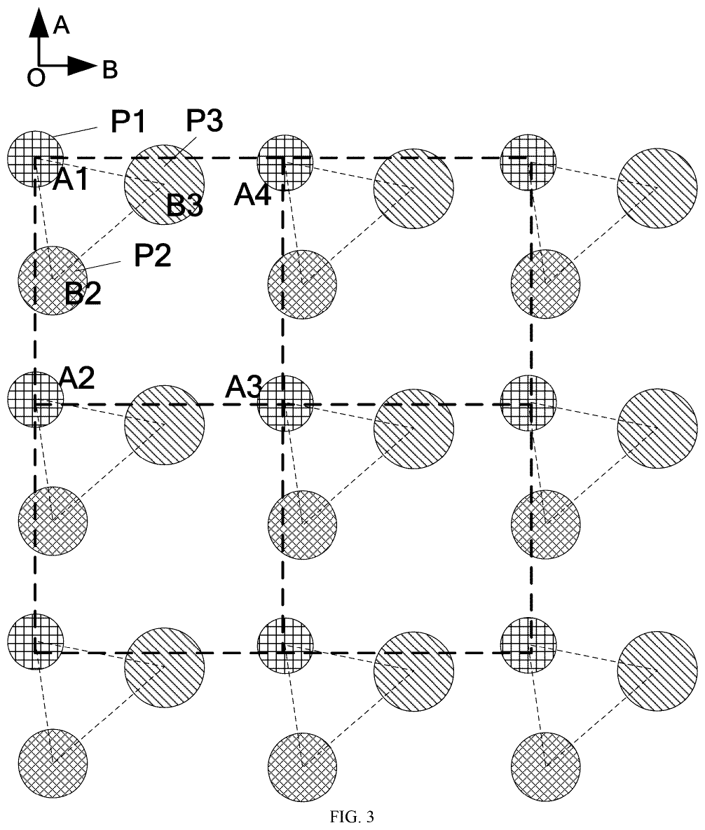

An embodiment of the present application provides a displaying base board, wherein the displaying base board comprises a substrate and a plurality of pixel units that are located on the substrate and are arranged in an array. As shown in FIG. 3, each of at least some of the pixel units comprises a first sub-pixel P1, a second sub-pixel P2 and a third sub-pixel P3. The center of the first sub-pixel P1, the center of the second sub-pixel P2 and the center of the third sub-pixel P3 are sequentially located at the vertex positions of a virtual triangle A1B2B3.

The connecting line between the center of the first sub-pixel P1 and the center of any one of the other sub-pixels (P2 or P3) in the same one pixel unit has an included angle with at least one of the first direction (for example, the direction OA) and the second direction (for example, the direction OB), wherein each of the first direction and the second direction is the direction of extension of the same one queue of the first sub-pixels P1, and the first direction and the second direction intersect. Both of more than a half of the region of the second sub-pixel P2 and at least a half of the region of the third sub-pixel P3 in the same one pixel unit are located on the same one side of the connecting line of the centers of the same one queue of the first sub-pixels P1.

In an exemplary embodiment, the substrate may be a rigid substrate, for example, a silicon substrate or a glass substrate. The substrate may be a flexible substrate, for example, flexible polyimide or another flexible polymer film.

In an exemplary embodiment, the displaying base board may be an Organic Light Emitting Diode (referred to for short as OLED) displaying base board. Alternatively, the displaying base board may be a Quantum-Dot Light Emitting Diode (referred to for short as QLED) displaying base board.

It should be noted that the embodiments of the present application illustrate by taking the case as an example in which the displaying base board is an OLED displaying base board. As an example, the displaying base board may be an OLED (Organic Light Emitting Diode) displaying base board. Alternatively, the displaying base board may also be a WOLED (White Organic Light Emitting Diode) displaying base board.

It should be noted that, in the displaying base board according to the embodiments of the present application, the type of the evaporation source in its OLED vapor-deposition technique is not limited, and the evaporation source of the vapor-deposition chamber includes but is not limited to a point source, a linear source and a planar source, which may be decided particularly according to the practical fabricating process.

In an exemplary embodiment, the sub-pixels of the OLED displaying base board comprise an OLED light emitting device. In some embodiments, the OLED light emitting device may comprise a single luminescent layer. In some other embodiments, the OLED light emitting device may comprise double luminescent layers, and an electric-charge generating layer (CGL) is added between the double luminescent layers, to realize a double-layer light emission (Tandem EL) design. The OLED light emitting device does not only comprise the film layer that directly emits light, but also comprises the functional film layers for assisting the light emission, for example, a hole transporting layer and an electron transporting layer.

It should be noted that all of the regions where the sub-pixels are located in the schematic planar structural diagrams of the displaying base board according to the embodiments of the present application refer to the regions of the sub-pixels that actually emit light or the pixel opening regions of the sub-pixels, and do not represent a limitation on the regions of the luminescent layers of the sub-pixels and the regions of the anodes of the sub-pixels. The regions of the sub-pixels that actually emit light or the pixel opening regions of the sub-pixels are the regions in the sub-pixels where the anode and the luminescence functional layer actually contact, and the luminescence functional layer comprises at least the luminescent layer.

In addition, all of the descriptions on, for example, “the edge of the sub-pixel” in the present application, unless stated otherwise, refer to the edge of the effective light emitting region of the sub-pixel (the region of the sub-pixel that actually emits light or the pixel opening region of the sub-pixel), and are not the edge of the luminescent layer or the edge of the anode. In fact, the edge of the effective light emitting region of the sub-pixel is located within the edge of its luminescent layer, and the edge of the effective light emitting region of the sub-pixel is located within the edge of its anode.

In an exemplary embodiment, the anodes of two neighboring sub-pixels have a gap therebetween.

In an exemplary embodiment, the minimum distance between the anodes of two neighboring sub-pixels in the same one pixel unit is less than or equal to the minimum distance between the anodes of two neighboring pixel units.

As an example, in the same one row of the pixel units, the minimum distance between the anodes of two neighboring sub-pixels in the same one pixel unit is less than or equal to the minimum distance between the anodes of two neighboring pixel units.

As an example, in the same one column of the pixel units, the minimum distance between the anodes of two neighboring sub-pixels in the same one pixel unit is less than or equal to the minimum distance between the anodes of two neighboring pixel units.

In an exemplary embodiment, within part of the region of the displaying base board, the luminescent layers of two neighboring sub-pixels are connected to (tangent to) or partially overlap with each other.

In an exemplary embodiment, in the same one pixel unit, the luminescent layers of two neighboring sub-pixels are connected to (tangent to) or partially overlap with each other.

As an example, in the same one pixel unit, the luminescent layer of the first sub-pixel P1 and the luminescent layer of the second sub-pixel P2 are connected to (tangent to) or partially overlap with each other, the luminescent layer of the first sub-pixel P1 and the luminescent layer of the third sub-pixel P3 are connected to (tangent to) or partially overlap with each other, and the luminescent layer of the second sub-pixel P2 and the luminescent layer of the third sub-pixel P3 have a gap therebetween.

As an example, in the same one pixel unit, the luminescent layer of the first sub-pixel P1 and the luminescent layer of the second sub-pixel P2 are connected to (tangent to) or partially overlap with each other, the luminescent layer of the first sub-pixel P1 and the luminescent layer of the third sub-pixel P3 are connected to (tangent to) or partially overlap with each other, and the luminescent layer of the second sub-pixel P2 and the luminescent layer of the third sub-pixel P3 are connected to (tangent to) or partially overlap with each other.

As an example, in the same one pixel unit, each two of the luminescent layer of the first sub-pixel P1, the luminescent layer of the second sub-pixel P2 and the luminescent layer of the third sub-pixel P3 are connected to each other, to form an entirety.

In an exemplary embodiment, regarding two neighboring pixel units, within at least part of the region exist two neighboring pixel units whose luminescent layers have a gap therebetween.

As an example, of two neighboring pixel units, all of the luminescent layers of the sub-pixels of a first pixel unit and the luminescent layers of the sub-pixels of a second pixel unit have a gap therebetween.

As an example, of two neighboring pixel units, the luminescent layers of some of the sub-pixels of a first pixel unit and the luminescent layers of some of the sub-pixels of a second pixel unit have a gap therebetween, and of the two neighboring pixel units, the luminescent layers of some of the sub-pixels of the first pixel unit and the luminescent layers of some of the sub-pixels of the second pixel unit are connected to each other.

As an example, of two neighboring pixel units, the luminescent layers of some of the sub-pixels of a first pixel unit and the luminescent layers of some of the sub-pixels of a second pixel unit have a gap therebetween, and of the two neighboring pixel units, the luminescent layers of some of the sub-pixels of the first pixel unit and the luminescent layers of some of the sub-pixels of the second pixel unit partially overlap.

As an example, in the direction of extension of the same one column of the pixel units, the luminescent layers of two neighboring pixel units may be connected to (tangent to) or partially overlap with each other. In the direction of extension of the same one row of the pixel units, the luminescent layers of two neighboring pixel units may be connected to (tangent to) or partially overlap with each other. In a third direction, the luminescent layers of two neighboring pixel units have a gap therebetween, wherein the direction of extension of the same one column of the pixel units and the direction of extension of the same one row of the pixel units are perpendicular, and the third direction intersects with each of the direction of extension of the same one column of the pixel units and the direction of extension of the same one row of the pixel units.

The planar patterns of the luminescent layers of the sub-pixels are not limited herein.

As an example, the planar patterns of the luminescent layers may be an arc shape, a polygon, or a combination of an are shape and a polygon.

For example, the are shape may include a circular shape, an elliptical shape, a semicircular shape, a semi-elliptical shape, a sector shape and a rounded-corner polygon. The polygon may include a tetragon, a pentagon, a hexagon and so on. The combination of an are shape and a polygon includes a pattern formed by adding an arc shape to a polygon, a pattern formed by removing an arc shape from a polygon, and a pattern formed by removing a polygon from an are shape.

It is not limited herein whether the planar patterns of the luminescent layer of the sub-pixel and the pixel opening region of the sub-pixel (the region of the sub-pixel that actually emits light) are the same. The planar pattern of the pixel opening region depends on the planar shape of the openings in a pixel defining layer PDL.

As an example, in the same one sub-pixel the planar pattern of the luminescent layer is larger than the planar pattern of the pixel opening region.

As an example, in the same one sub-pixel the planar pattern of the luminescent layer is different from the planar pattern of the pixel opening region.

As an example, in the same one sub-pixel the planar pattern of the luminescent layer is the same as the planar pattern of the pixel opening region.

In order to reduce the difficulty in the vapor deposition of the luminescent layers in the vapor-deposition process, it may be configured that the shapes of the planar patterns of the luminescent layers of all of the sub-pixels are the same, and, by configuring that the planar patterns of the pixel opening regions of the different sub-pixels in the same one pixel unit are different, the sub-pixels of different shapes are fabricated. Alternatively, it may be configured that the sizes of the planar patterns of the luminescent layers of all of the sub-pixels are equal, and, by configuring that the sizes of the planar patterns of the pixel opening regions of the different sub-pixels in the same one pixel unit are unequal, the sub-pixels of unequal sizes are fabricated.

It should be noted that, in the case in which the luminescent layers of two sub-pixels are connected to (tangent to) each other:

For example, the luminescent layer of the first sub-pixel P1 and the luminescent layer of the second sub-pixel P2 are tangent, in which case the distance between the point of tangency and the edge of the effective light emitting region of the first sub-pixel P1 is substantially equal to the distance between the point of tangency and the edge of the effective light emitting region of the second sub-pixel P2.

As another example, the luminescent layer of the first sub-pixel P1 and the luminescent layer of the third sub-pixel P3 are tangent, in which case the distance between the point of tangency and the edge of the effective light emitting region of the first sub-pixel P1 is substantially equal to the distance between the point of tangency and the edge of the effective light emitting region of the third sub-pixel P3.

As another example, the luminescent layer of the second sub-pixel P2 and the luminescent layer of the third sub-pixel P3 are tangent, in which case the distance between the point of tangency and the edge of the effective light emitting region of the second sub-pixel P2 is substantially equal to the distance between the point of tangency and the edge of the effective light emitting region of the third sub-pixel P3.

In an exemplary embodiment, the “at least some of the pixel units” refer to some of the pixel units of the displaying base board or all of the pixel units of the displaying base board.

The above-described “located” generally refers to that the center points of the sub-pixels (P1, P2 and P3) substantially overlap at the vertex positions of the virtual triangle A1B2B3.

The center of each of the sub-pixels may be the geometric center of the pattern of the sub-pixel, and may also be the center of the light emitting region of the sub-pixel, wherein the center of the light emitting region refers to the position having the highest luminous intensity. The meanings of the “center” at the other positions in the present application are similar to the above-described situation, and are not discussed further.

In an exemplary embodiment, the shapes of the sub-pixels may be polygons, for example, regular polygons such as a triangle, a tetragon and a pentagon. Alternatively, the shapes of the sub-pixels may be polygons having at least one rounded corner, for example, a rounded-corner tetragon and a rounded-comer pentagon. Alternatively, the shapes of the sub-pixels may be irregular shapes obtained by removing or adding a part based on polygons.

In an exemplary embodiment, the shapes of the sub-pixels may be are shapes, for example, a circular shape, an elliptical shape, a semicircular shape and a semi-elliptical shape.

It should be noted that the virtual shapes according to the embodiments of the present application, for example, the virtual triangle described above, and the virtual tetragon and the virtual rectangle described below, do not exist actually, and are merely concepts that are provided in order to facilitate to describe the position relation of the sub-pixels.

In the embodiments of the present application, two neighboring virtual triangles do not overlap, and have a gap therebetween.

All of the figures according to the embodiments of the present application illustrate the state of the distribution of the sub-pixels in the displaying base board with the pixel opening region as the representative. The light emitting region (also referred to as a pixel opening region) refers to the region in the sub-pixel where the light rays exit.

That “the connecting line between the center of the first sub-pixel P1 and the center of any one of the other sub-pixels (P2 or P3) in the same one pixel unit has an included angle with at least one of the first direction (for example, the direction OA) and the second direction (for example, the direction OB)” includes but is not limited to the following cases:

In the first case, the connecting line between the center of the first sub-pixel P1 and the center of the second sub-pixel P2 in the same one pixel unit has an included angle with at least one of the first direction (for example, the direction OA) and the second direction (for example, the direction OB).

For example, the connecting line between the center of the first sub-pixel P1 and the center of the second sub-pixel P2 in the same one pixel unit has an included angle with the first direction (for example, the direction OA), and the connecting line between the center of the first sub-pixel P1 and the center of the second sub-pixel P2 in the same one pixel unit has an included angle with the second direction (for example, the direction OB).

In the second case, the connecting line between the center of the first sub-pixel P1 and the center of the third sub-pixel P3 in the same one pixel unit has an included angle with at least one of the first direction (for example, the direction OA) and the second direction (for example, the direction OB).

For example, the connecting line between the center of the first sub-pixel P1 and the center of the third sub-pixel P3 in the same one pixel unit has an included angle with the first direction (for example, the direction OA), and the connecting line between the center of the first sub-pixel P1 and the center of the third sub-pixel P3 in the same one pixel unit is substantially parallel to the second direction (for example, the direction OB).

As another example, the connecting line between the center of the first sub-pixel P1 and the center of the third sub-pixel P3 in the same one pixel unit has an included angle with the first direction (for example, the direction OA), and the connecting line between the center of the first sub-pixel P1 and the center of the third sub-pixel P3 in the same one pixel unit also has an included angle with the second direction (for example, the direction OB).

It should be noted that, in the description, the descriptions on “having an included angle” refer to that the included angle is not 0°.

Each of the first direction and the second direction is the direction of extension of the same one queue of the first sub-pixels P1, and the first direction and the second direction intersect.

As an example, the same one queue may include any one of the same one row and the same one column.

As an example, the first direction may be the direction of extension of the same one column of the first sub-pixels P1, and the second direction may be the direction of extension of the same one row of the first sub-pixels P1.

The “at least a half of the region” includes a half of the region and more than a half of the region.

That “both of more than a half of the region of the second sub-pixel P2 and at least a half of the region of the third sub-pixel P3 in the same one pixel unit are located on the same one side of the connecting line of the centers of the same one queue of the first sub-pixels P1” includes but is not limited to the following cases:

In the first case, both of more than a half of the region of the second sub-pixel P2 and more than a half of the region of the third sub-pixel P3 in the same one pixel unit are located on the same one side of the connecting line of the centers of the same one row of the first sub-pixels P1.

In the second case, both of more than a half of the region of the second sub-pixel P2 and more than a half of the region of the third sub-pixel P3 in the same one pixel unit are located on the same one side of the connecting line of the centers of the same one column of the first sub-pixels P1.

In the third case, both of more than a half of the region of the second sub-pixel P2 and more than a half of the region of the third sub-pixel P3 in the same one pixel unit are located on the same one side of the connecting line of the centers of the same one row of the first sub-pixels P1, and both of more than a half of the region of the second sub-pixel P2 and more than a half of the region of the third sub-pixel P3 in the same one pixel unit are located on the same one side of the connecting line of the centers of the same one column of the first sub-pixels P1.

In the fourth case, both of more than a half of the region of the second sub-pixel P2 and a half of the region of the third sub-pixel P3 in the same one pixel unit are located on the same one side of the connecting line of the centers of the same one row of the first sub-pixels P1.

The displaying colors of the sub-pixels are not limited herein.

In some embodiments, all of the displaying colors of the sub-pixels may be the same. For example, all of the sub-pixels display the blue color. As another example, all of the sub-pixels display the white color.

In some other embodiments, the displaying base board may comprise multiple types of the sub-pixels of different displaying colors. For example, the displaying base board may comprise all of three types of the sub-pixels that display the red color, the blue color and the green color.

It should be noted that, no matter how the sub-pixels in the same one pixel unit are arranged, gaps exist between each two of the three types of sub-pixels, to prevent cross-color.

The colors of each two of the first sub-pixel P1, the second sub-pixel P2 and the third sub-pixel P3 are different. As an example, the colors of the first sub-pixel P1, the second sub-pixel P2 and the third sub-pixel P3 are one of the red color, the green color and the blue color individually.

For example, the first sub-pixel P1 is a red-color sub-pixel, the second sub-pixel P2 is a green-color sub-pixel, and the third sub-pixel P3 is a blue-color sub-pixel. Alternatively, the first sub-pixel P1 is a blue-color sub-pixel, the second sub-pixel P2 is a red-color sub-pixel, and the third sub-pixel P3 is a green-color sub-pixel. Alternatively, the first sub-pixel P1 is a green-color sub-pixel, the second sub-pixel P2 is a blue-color sub-pixel, and the third sub-pixel P3 is a red-color sub-pixel. Alternatively, the first sub-pixel P1 is a red-color sub-pixel, the second sub-pixel P2 is a blue-color sub-pixel, and the third sub-pixel P3 is a green-color sub-pixel. Alternatively, the first sub-pixel P1 is a blue-color sub-pixel, the second sub-pixel P2 is a green-color sub-pixel, and the third sub-pixel P3 is a red-color sub-pixel. Those may be decided particularly according to practical design demands. The embodiments of the present application illustrate by taking the case as an example in which the first sub-pixel P1 is a red-color sub-pixel, the second sub-pixel P2 is a green-color sub-pixel and the third sub-pixel P3 is a blue-color sub-pixel.

In an exemplary embodiment, each of the sub-pixels further comprises a pixel driving circuit, in the same one pixel unit, the pixel driving circuits of the sub-pixels are arranged side by side. Regarding the same one queue of the sub-pixels, no matter whether the connecting line of the centers (the geometric centers of the pixel opening regions or the light-emission centers) of the same one queue of the sub-pixels is a straight line or a folding line, the pixel driving circuits of the same one queue of the sub-pixels are arranged in the same one straight line.

In an exemplary embodiment, the pixel driving circuit of the first sub-pixel P1 has an overlapping part with the luminescent layer of the second sub-pixel P2 and the luminescent layer of the third sub-pixel P3 individually, the pixel driving circuit of the second sub-pixel P2 has an overlapping part with the luminescent layer of the second sub-pixel P2 and the luminescent layer of the third sub-pixel P3 individually, and the pixel driving circuit of the third sub-pixel P3 has an overlapping part with the luminescent layer of the third sub-pixel P3, and the luminescent layer of the first sub-pixel P1 in another pixel unit individually.

The particular structures of the pixel driving circuits are not limited herein. As an example, the pixel driving circuits may include driving circuits of the structures such as 7T2C and 5T2C, wherein T represents a transistor and C represents a capacitor.

In the displaying base board according to the embodiments of the present application, in the practical vapor-deposition process, when the linear-source distribution direction is the same as the first direction, and the linear-source vapor-deposition scanning direction is the same as the second direction, the connecting line between the center of the first sub-pixel and the center of the second sub-pixel (the third sub-pixel) has an included angle with at least one of the first direction and the second direction, and both of more than a half of the region of the second sub-pixel P2 and at least a half of the region of the third sub-pixel P3 in the same one pixel unit are located on the same one side of the connecting line of the centers of the same one queue of the first sub-pixels P1. Accordingly, in an aspect, the problem in the related art of the color mixing caused by the film-layer overlapping between two sub-pixels arranged in the linear-source distribution direction can be ameliorated, which improves the effect of displaying of the displaying base board to a large extent. In another aspect, while the sizes of the pixel openings of the sub-pixels are maintained constant, the spacing (Gap) between two neighboring sub-pixels can be increased, which further reduces the problem of the color mixing caused by the film-layer overlapping between two sub-pixels. In yet another aspect, while the spacing (Gap) between two neighboring sub-pixels is maintained constant, more design room can be used to increase the pixel openings (for example, increasing the areas of the anodes of the sub-pixels), thereby increasing the aperture ratio, to increase the light transmittance and the optical efficiency of the displaying base board. As shown by the data in Table 1, the aperture ratio of the displaying base board according to the embodiments of the present application can be increased up to 9.38%.

TABLE 1
data of the comparison between the aperture ratios in products
of different resolutions (PPI) of a displaying base board in
the related art (Nor.) and the displaying base board
according to the present application.

| PPI | Nor. | the present application |
|---|---|---|
| 320 | 17.90% | 19.5% (↑9.38) |
| 240 | 27.07% | 28.9% (↑6.77) |
| 185 | 34.46% | 36.4% (↑5.66) |

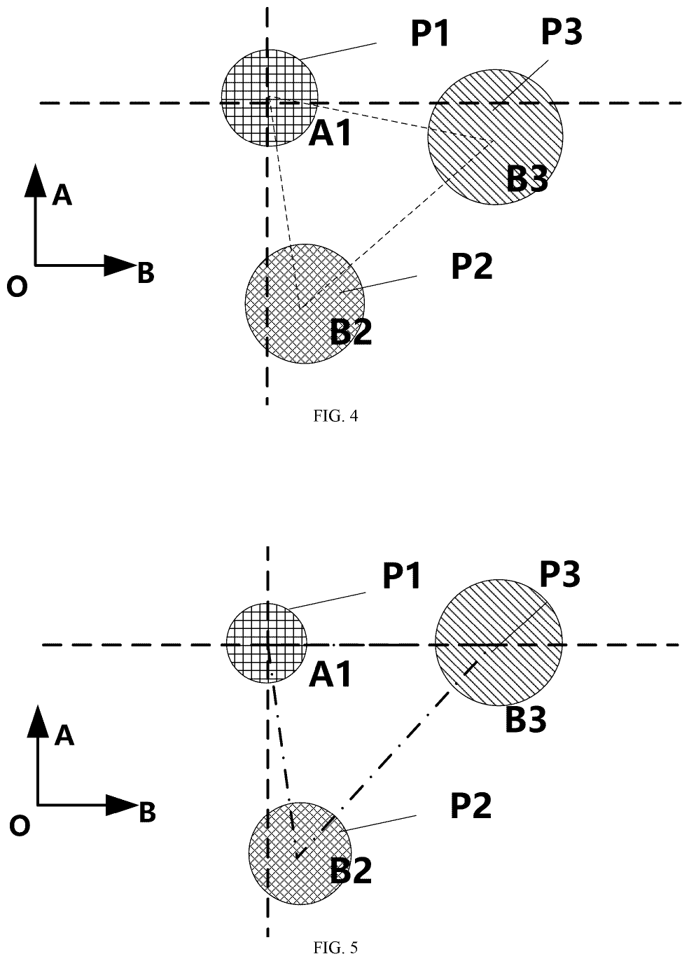

In at least one embodiment of the present application, as shown in FIGS. 3 and 4, the connecting line between the center of the first sub-pixel P1 and the center of the any one of the other sub-pixels in the same one pixel unit has included angles with both of the first direction and the second direction.

As an example, the connecting line A1B2 between the center of the first sub-pixel P1 and the center of the second sub-pixel P2 in the same one pixel unit has included angles with both of the first direction and the second direction.

For example, the connecting line A1B2 between the center of the first sub-pixel P1 and the center of the second sub-pixel P2 in the same one pixel unit has an included angle with the connecting line A1A2 of the centers of two neighboring rows of the first sub-pixels P1, and the connecting line A1B2 between the center of the first sub-pixel P1 and the center of the second sub-pixel P2 in the same one pixel unit has an included angle with the connecting line A1A4 of the centers of two neighboring columns of the first sub-pixels P1.

As an example, the connecting line A1B3 between the center of the first sub-pixel P1 and the center of the third sub-pixel P3 in the same one pixel unit has included angles with both of the first direction (for example, the direction OA) and the second direction (for example, the direction OB).

For example, the connecting line A1B3 between the center of the first sub-pixel P1 and the center of the third sub-pixel P3 in the same one pixel unit has an included angle with the connecting line A1A2 of the centers of two neighboring rows of the first sub-pixels P1, and the connecting line A1B3 between the center of the first sub-pixel P1 and the center of the third sub-pixel P3 in the same one pixel unit has an included angle with the connecting line A1A4 of the centers of two neighboring columns of the first sub-pixels P1.

As an example, the connecting line between the centers of any two sub-pixels in the same one pixel unit has included angles with both of the first direction and the second direction.

For example, the connecting line between the centers of any two sub-pixels in the same one pixel unit includes the connecting line A1B3 between the centers of the first sub-pixel P1 and the third sub-pixel P3, the connecting line A1B2 between the centers of the first sub-pixel P1 and the second sub-pixel P2, and the connecting line B2B3 between the centers of the second sub-pixel P2 and the third sub-pixel P3.

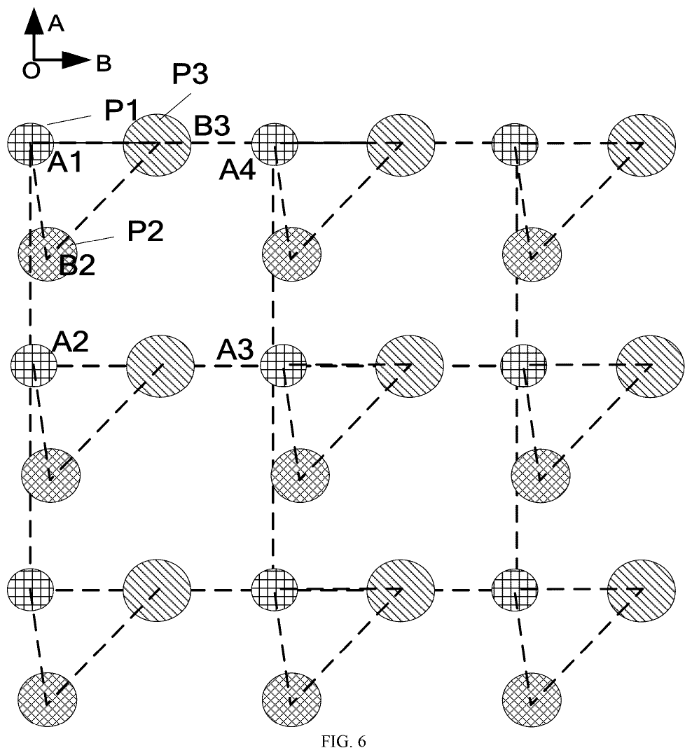

In at least one embodiment of the present application, as shown in FIGS. 5 and 6, the connecting line A1B2 between the center of the first sub-pixel P1 and the center of the second sub-pixel P2 in the same one pixel unit has an included angle with the first direction (for example, the direction OA), wherein the first direction is the direction of extension of the same one column of the first sub-pixels P1.

As an example, the figures according to the embodiments of the present application illustrate by taking the case as an example in which the first direction is the vertical direction and the second direction is the horizontal direction.

In at least one embodiment of the present application, as shown in FIGS. 3 and 6, four first sub-pixels P1 are located at the vertex positions of a first virtual tetragon A1A2A3A4, the virtual triangle A1B2B3 is located within the first virtual tetragon A1A2A3A4, and the first virtual tetragon A1A2A3A4 and the virtual triangle A1B2B3 share one vertex A1.

In an exemplary embodiment, the interior angles of the virtual triangle A1B2B3 are less than or equal to 90°.

For example, the virtual triangle A1B2B3 is an acute triangle.

For example, the three angles of the virtual triangle A1B2B3 are 56°, 56° and 68°. Alternatively, the three angles of the virtual triangle A1B2B3 are 55°, 56° and 69°.

For example, the virtual triangle A1B2B3 is an isosceles triangle.

As an example, the lateral side A1B2 of the virtual triangle is substantially equal to the lateral side A1B3 of the virtual triangle.

Alternatively, the lateral side A1B3 of the virtual triangle is substantially equal to the lateral side B2B3 of the virtual triangle.

Alternatively, the lateral side A1B2 of the virtual triangle is substantially equal to the lateral side B2B3 of the virtual triangle.

As another example, the virtual triangle A1B2B3 is an equilateral triangle.

In an exemplary embodiment, the first virtual tetragon A1A2A3A4 may be a parallelogram. For example, the first virtual tetragon A1A2A3A4 may be a rhombus, a rectangle or a square.

That four first sub-pixels P1 are located at the vertex positions of a first virtual tetragon A1A2A3A4 refers to that the centers of the four first sub-pixels P1 are located at the four vertex positions of the first virtual tetragon A1A2A3A4, and, besides the four first sub-pixels P1, within the first virtual tetragon A1A2A3A4 there is no other first sub-pixel P1, wherein the “center” refers to the geometric center or the light-emission center of the sub-pixel.

In an exemplary embodiment, the connecting line of the centers of the same one queue of the sub-pixels includes a folding line. That the connecting line of the centers of the same one queue of the sub-pixels includes a folding line may include the following cases:

In the first case, the connecting line of the centers of the same one row of the sub-pixels includes a folding line.

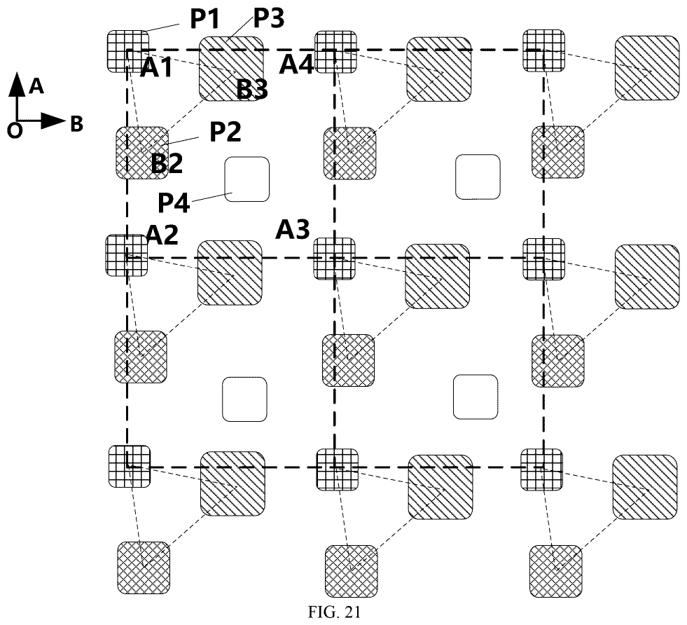

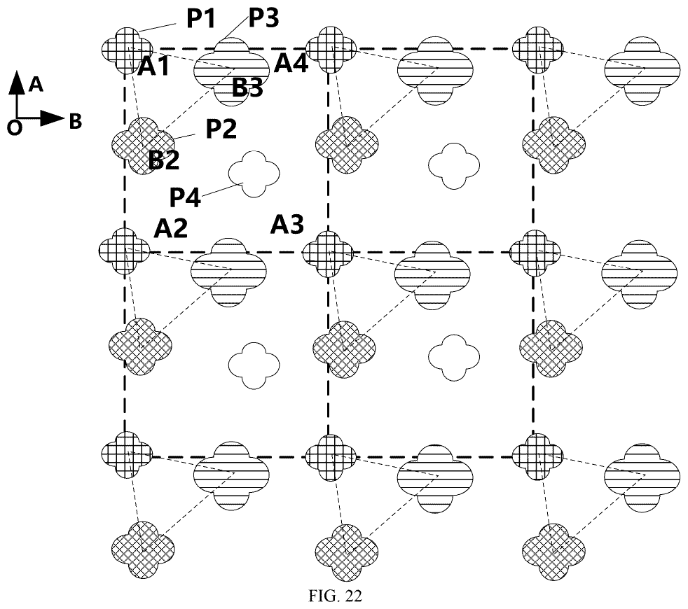

For example, as shown in FIGS. 3, 15-19 and 21-22, the same one row of the sub-pixels include a plurality of first sub-pixels P1 and a plurality of third sub-pixels P3, and in the sub-pixel row formed by the plurality of first sub-pixels P1 and the plurality of third sub-pixels P3, the connecting line of the centers of the sub-pixels is a folding line.

In the second case, the connecting line of the centers of the same one column of the sub-pixels includes a folding line.

For example, as shown in FIGS. 3 and 15-22, the same one column of the sub-pixels include a plurality of first sub-pixels P1 and a plurality of second sub-pixels P2, and in the sub-pixel column formed by the plurality of first sub-pixels P1 and the plurality of second sub-pixels P2, the connecting line of the centers of the sub-pixels is a folding line.

In the third case, the connecting line of the centers of the same one row of the sub-pixels includes a folding line, and the connecting line of the centers of the same one column of the sub-pixels includes a folding line.

For example, as shown in FIGS. 3, 15-19 and 21-22, the same one row of the sub-pixels include a plurality of first sub-pixels P1 and a plurality of third sub-pixels P3, and in the sub-pixel row formed by the plurality of first sub-pixels P1 and the plurality of third sub-pixels P3, the connecting line of the centers of the sub-pixels is a folding line. The same one column of the sub-pixels include a plurality of first sub-pixels P1 and a plurality of second sub-pixels P2, and in the sub-pixel column formed by the plurality of first sub-pixels P1 and the plurality of second sub-pixels P2, the connecting line of the centers of the sub-pixels is a folding line.

Certainly, in some embodiments, the connecting line of the centers of the same one queue of the sub-pixels includes a straight line.

As an example, as shown in FIGS. 6, 10 and 20, the same one row of the sub-pixels include a plurality of first sub-pixels P1 and a plurality of third sub-pixels P3, and in the sub-pixel row formed by the plurality of first sub-pixels P1 and the plurality of third sub-pixels P3, the connecting line of the centers of the sub-pixels is a straight line.

In at least one embodiment of the present application, in the same one pixel unit, at least two of the distance between the center of the first sub-pixel P1 and the center of the second sub-pixel P2, the distance between the center of the first sub-pixel P1 and the center of the third sub-pixel P3, and the distance between the center of the second sub-pixel P2 and the center of the third sub-pixel P3 are substantially equal.

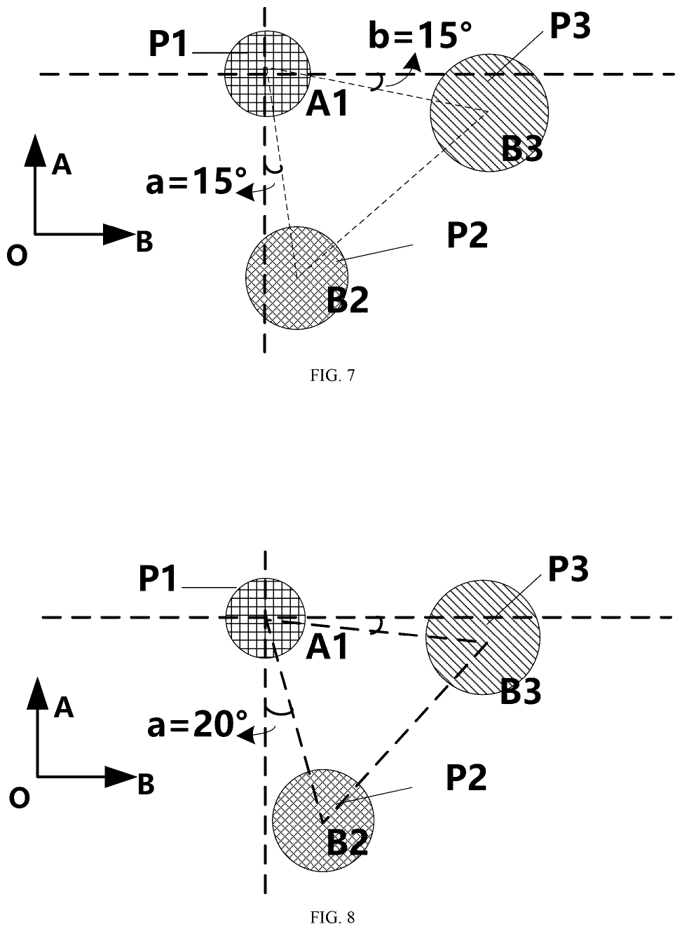

In an exemplary embodiment of the present application, as shown in FIG. 7, the distance A1B2 between the center of the first sub-pixel P1 and the center of the second sub-pixel P2 and the distance A1B3 between the center of the first sub-pixel P1 and the center of the third sub-pixel P3 are substantially equal.

In an exemplary embodiment of the present application, the distance A1B2 between the center of the first sub-pixel P1 and the center of the second sub-pixel P2 and the distance B3B2 between the center of the third sub-pixel P3 and the center of the second sub-pixel P2 are substantially equal.

In an exemplary embodiment of the present application, the distance B3B2 between the center of the third sub-pixel P3 and the center of the second sub-pixel P2 and the distance B3A1 between the center of the third sub-pixel P3 and the center of the first sub-pixel P1 are substantially equal.

In an exemplary embodiment of the present application, all of the distance between the center of the first sub-pixel P1 and the center of the second sub-pixel P2, the distance between the center of the first sub-pixel P1 and the center of the third sub-pixel P3, and the distance between the center of the second sub-pixel P2 and the center of the third sub-pixel P3 are substantially equal.

It should be emphasized that, in the description of the present application, the being “substantially equal” includes being equal and that the difference between the numerical values of two distances is less than or equal to 0.1 μm.

In at least one embodiment of the present application, as shown in FIGS. 3, 6 and 10, the first direction is the direction of extension of the same one column of the first sub-pixels P1, the second direction is the direction of extension of the same one row of the first sub-pixels P1, the first virtual tetragon A1A2A3A4 comprises a first lateral side A1A2 extending in the first direction and a second lateral side A1A4 extending in the second direction, the first lateral side A1A2 and the second lateral side A1A4 intersect at a first vertex A1, the first sub-pixel P1 in the same one pixel unit is located at the first vertex A1, the orthographic projection of the second sub-pixel P2 on the substrate and the orthographic projection of the first lateral side A1A2 on the substrate at least partially do not overlap, and the orthographic projection of the third sub-pixel P3 on the substrate and the orthographic projection of the second lateral side A1A4 on the substrate partially overlap.

The orthographic projection of the second sub-pixel P2 on the substrate and the orthographic projection of the first lateral side A1A2 on the substrate at least partially do not overlap, includes but is not limited to the following cases:

In the first case, as shown in FIGS. 3 and 6, the orthographic projection of the second sub-pixel P2 on the substrate and the orthographic projection of the first lateral side A1A2 on the substrate partially do not overlap.

In the second case, as shown in FIG. 10, the orthographic projection of the second sub-pixel P2 on the substrate and the orthographic projection of the first lateral side A1A2 on the substrate do not overlap with each other, and the orthographic projection of the second sub-pixel P2 on the substrate is located within the first virtual tetragon A1A2A3A4.

In at least one embodiment of the present application, as shown in FIGS. 3, 6 and 10, in one first virtual tetragon A1A2A3A4, one pixel unit exists in which the area of the region of the pixel unit that is located within the first virtual tetragon is greater than the area of the region of the pixel unit that is located outside the first virtual tetragon. It can be understood that, within one first virtual tetragon A1A2A3A4, the main body part of merely one pixel unit is provided.

In at least one embodiment of the present application, the distance A1B2 between the center of the first sub-pixel P1 and the center of the second sub-pixel P2 in the same one pixel unit is greater than or equal to a half of the side length of the first lateral side A1A2 of the first virtual tetragon A1A2A3A4 (½ of A1A2).

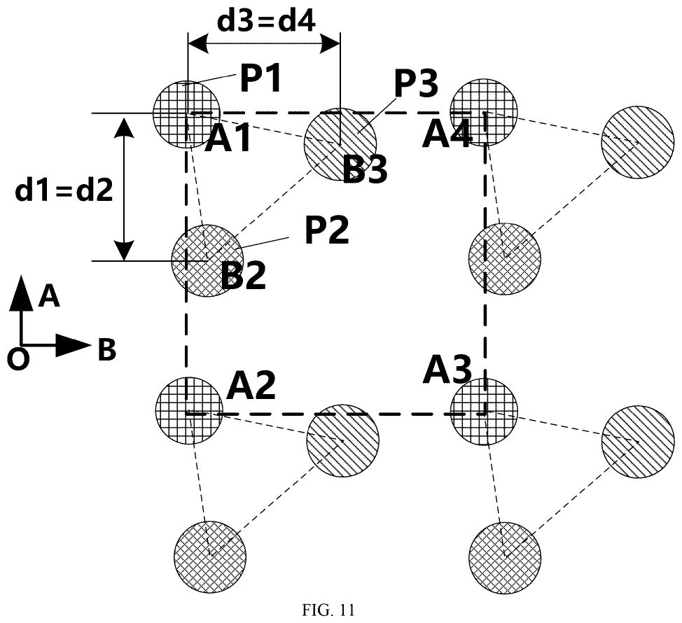

As an example, as shown in FIG. 11, the distance d2 between the center of the first sub-pixel P1 and the center of the second sub-pixel P2 in the same one pixel unit is equal to a half d1 of the side length of the first lateral side A1A2 of the first virtual tetragon A1A2A3A4.

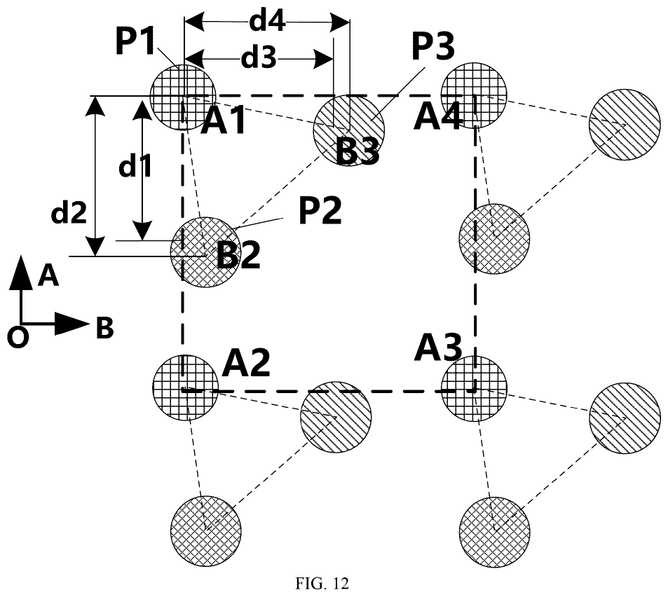

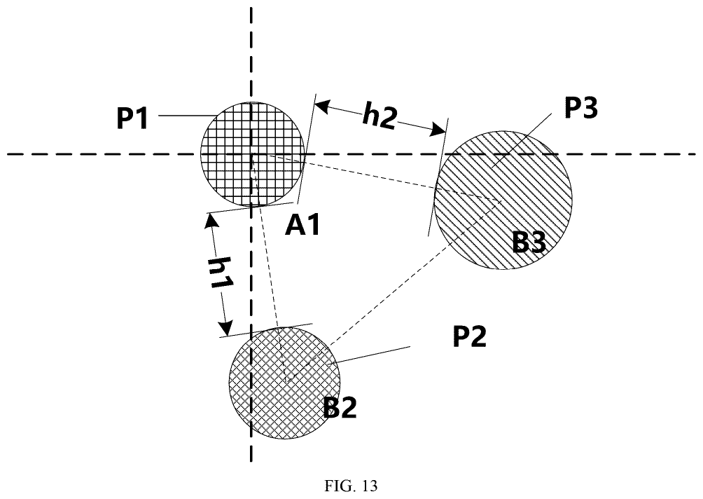

As an example, as shown in FIG. 12, the distance d2 between the center of the first sub-pixel P1 and the center of the second sub-pixel P2 in the same one pixel unit is greater than a half d1 of the side length of the first lateral side A1A2 of the first virtual tetragon A1A2A3A4.

In the displaying base board according to the embodiments of the present application, by configuring that the distance A1B2 between the center of the first sub-pixel P1 and the center of the second sub-pixel P2 in the same one pixel unit is greater than or equal to a half of the side length of the first lateral side A1A2 of the first virtual tetragon A1A2A3A4 (½ of A1A2), the spacing between the neighboring first sub-pixel P1 and second sub-pixel P2 is increased (the PDL Gap is increased), which further increases the spacing between the luminescent layers of the neighboring first sub-pixel P1 and second sub-pixel P2, to further prevent the problem of color mixing caused by the film-layer overlapping between the luminescent layers of the neighboring first sub-pixel P1 and second sub-pixel P2 in the vapor-deposition process, thereby improving the effect of displaying of the displaying base board.

It should be noted that the displaying base board further comprises the pixel defining layer located on the substrate, and the pixel defining layer is partially located on the side of the anodes that is farther from the substrate. The pixel defining layer comprises a plurality of pixel opening regions and pixel separating parts, and the pixel separating parts are located between two neighboring pixel opening regions. The plurality of pixel openings correspond to the plurality of sub-pixels one to one to define the effective light emitting regions of the plurality of sub-pixels. The pixel opening regions are configured for exposing the anodes, to facilitate the anodes to contact the subsequently formed luminescence functional layers, and the planar shapes of the pixel opening regions decide the shapes of the planar patterns of the sub-pixels in the displaying base board according to the embodiments of the present application. The luminescence functional layer may comprise other functional sub-layers than the electric-charge generating layer and the luminescent layer, for example, a hole injection layer, a hole transporting layer, an electron injection layer and an electron transporting layer. The spacing between the neighboring first sub-pixel P1 and second sub-pixel P2 (PDL Gap) refers to the width of the pixel separating part between the pixel opening region where the first sub-pixel P1 is provided and the pixel opening region where the second sub-pixel P2 is provided.

In at least one embodiment of the present application, the distance between the center of the first sub-pixel P1 and the center of the third sub-pixel P3 in the same one pixel unit is greater than or equal to a half of the side length of the second lateral side A1A4 of the first virtual tetragon A1A2A3A4 (½ of A1A4).

As an example, as shown in FIG. 11, the distance d4 between the center of the first sub-pixel P1 and the center of the third sub-pixel P3 in the same one pixel unit is equal to a half d3 of the side length of the second lateral side A1A4 of the first virtual tetragon A1A2A3A4.

As an example, as shown in FIG. 12, the distance d4 between the center of the first sub-pixel P1 and the center of the third sub-pixel P3 in the same one pixel unit is greater than a half d3 of the side length of the second lateral side A1A4 of the first virtual tetragon A1A2A3A4.

In the displaying base board according to the embodiments of the present application, by configuring that the distance between the center of the first sub-pixel P1 and the center of the third sub-pixel P3 in the same one pixel unit is greater than or equal to a half of the side length of the second lateral side A1A4 of the first virtual tetragon A1A2A3A4 (½ of A1A4), the spacing between the neighboring first sub-pixel P1 and third sub-pixel P3 is increased (the PDL Gap is increased), which further increases the spacing between the luminescent layers of the neighboring first sub-pixel P1 and third sub-pixel P3, to further prevent the problem of color mixing caused by the film-layer overlapping between the luminescent layers of the neighboring first sub-pixel P1 and third sub-pixel P3 in the vapor-deposition process, thereby improving the effect of displaying of the displaying base board.

In at least one embodiment of the present application, as shown in FIG. 13, in the same one pixel unit, the minimum distance h1 between the edge of the first sub-pixel P1 and the edge of the second sub-pixel P2 and the minimum distance h2 between the edge of the first sub-pixel P1 and the edge of the third sub-pixel P3 are substantially equal.

In the embodiments of the present application, by configuring that the minimum distance h1 between the edge of the first sub-pixel P1 and the edge of the second sub-pixel P2 and the minimum distance h2 between the edge of the first sub-pixel P1 and the edge of the third sub-pixel P3 are substantially equal, the probability in color mixing between the first sub-pixel P1 and the second sub-pixel P2 and the probability in color mixing between the first sub-pixel P1 and the third sub-pixel P3 can be reduced, to take into consideration and ameliorate the problem of color mixing between the first sub-pixel P1 and the second sub-pixel P2 and the problem of color mixing between the first sub-pixel P1 and the third sub-pixel P3 at the same time, thereby further improving the effect of displaying of the displaying base board.

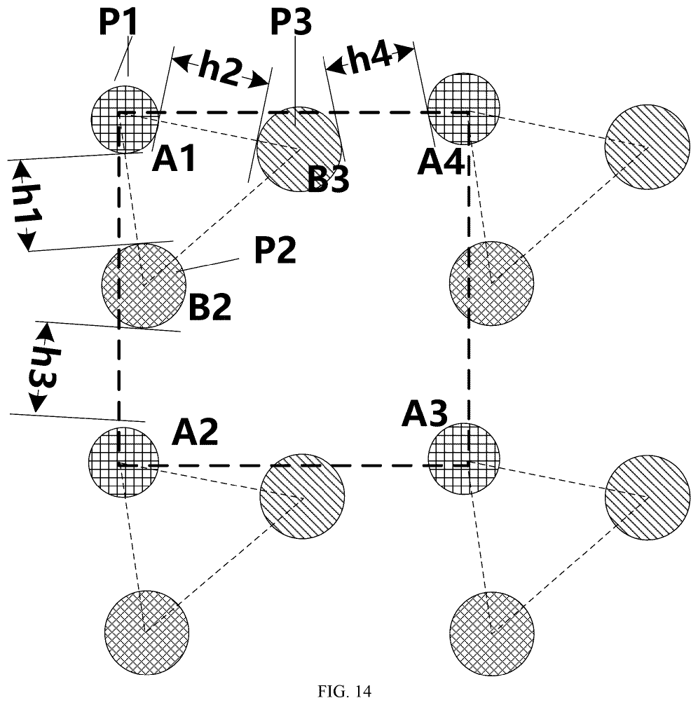

In at least one embodiment of the present application, as shown in FIG. 14, the minimum distance h2 between the edge of the third sub-pixel P3 and the edge of the first sub-pixel P1 in the same one pixel unit is substantially equal to the minimum distance h4 from the edge of the third sub-pixel P3 to the edge of the first sub-pixel P3 in a neighboring pixel unit. The minimum distance h1 between the edge of the second sub-pixel P2 and the edge of the first sub-pixel P1 in the same one pixel unit is substantially equal to the minimum distance h3 from the edge of the second sub-pixel P2 to the edge of the first sub-pixel P1 in the neighboring pixel unit.

In the embodiments of the present application, by configuring that the minimum distance h2 between the edge of the third sub-pixel P3 and the edge of the first sub-pixel P1 in the same one pixel unit is substantially equal to the minimum distance h4 from the edge of the third sub-pixel P3 to the edge of the first sub-pixel P3 in a neighboring pixel unit, and the minimum distance h1 between the edge of the second sub-pixel P2 and the edge of the first sub-pixel P1 in the same one pixel unit is substantially equal to the minimum distance h3 from the edge of the second sub-pixel P2 to the edge of the first sub-pixel P1 in the neighboring pixel unit, the probability in color mixing between the first sub-pixel P1 and the second sub-pixel P2 and the probability in color mixing between the first sub-pixel P1 and the third sub-pixel P3 can be reduced, to take into consideration and ameliorate the problem of color mixing between the first sub-pixel P1 and the second sub-pixel P2 and the problem of color mixing between the first sub-pixel P1 and the third sub-pixel P3 at the same time, thereby further improving the effect of displaying of the displaying base board.

In at least one embodiment of the present application, as shown in FIGS. 7, 8 and 9, the virtual triangle A1B2B3 is an acute triangle, and the included angle between the connecting line between the center of the first sub-pixel P1 and the center of the any one of the other sub-pixels in the same one pixel unit and the at least one of the first direction and the second direction is greater than 0° and less than or equal to 30°.

As an example, as shown in FIGS. 7, 8 and 9, the included angle between the connecting line between the center of the first sub-pixel P1 and the center of the second sub-pixel P2 in the same one pixel unit and the first direction (the direction OA) is greater than 0° and less than or equal to 30°.

As an example, as shown in FIGS. 7 and 8, the included angle between the connecting line between the center of the first sub-pixel P1 and the center of the third sub-pixel P3 in the same one pixel unit and the second direction (the direction OB) is greater than 0° and less than or equal to 30°.

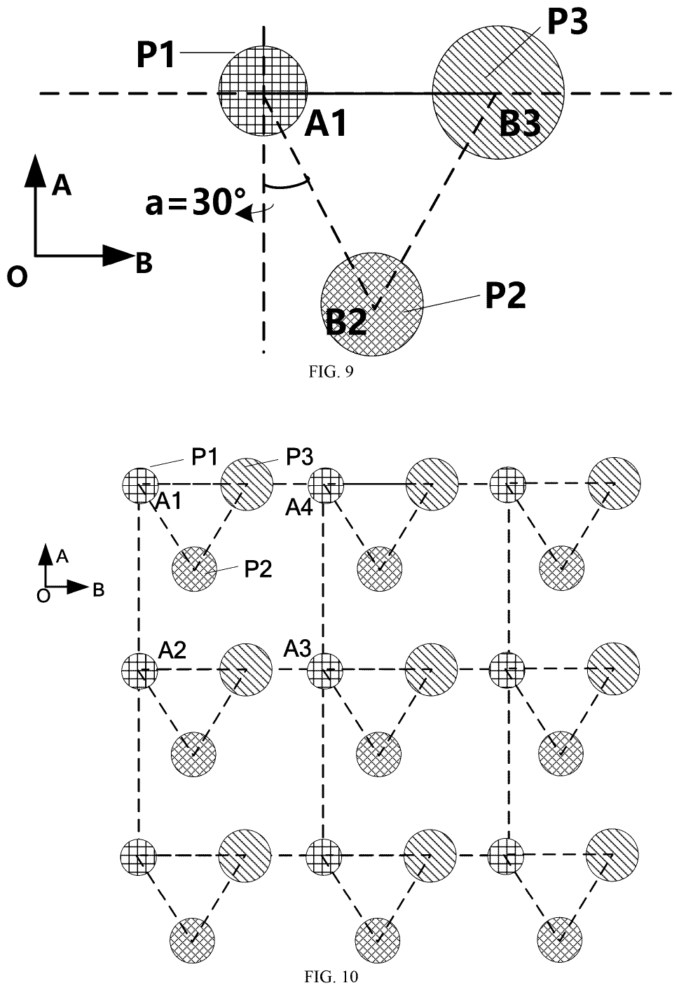

As an example, as shown in FIG. 9, the direction of extension of the connecting line between the center of the first sub-pixel P1 and the center of the third sub-pixel P3 in the same one pixel unit is the same as the second direction (the direction OB), and the included angle between the connecting line between the center of the first sub-pixel P1 and the center of the second sub-pixel P2 in the same one pixel unit and the first direction (the direction OA) is 30°.

In at least one embodiment of the present application, an included angle between the connecting line between the center of the first sub-pixel P1 and the center of the second sub-pixel P2 in the same one pixel unit and the direction of extension of the same one column of the first sub-pixels P1 is substantially equal to an included angle between the connecting line between the center of the first sub-pixel P1 and the center of the third sub-pixel P3 and the direction of extension of the same one row of the first sub-pixels P1.

For example, as shown in FIG. 7, the included angle between the connecting line between the center of the first sub-pixel P1 and the center of the second sub-pixel P2 in the same one pixel unit and the direction of extension of the same one column of the first sub-pixels P1 is substantially 15°, and the included angle between the connecting line between the center of the first sub-pixel P1 and the center of the third sub-pixel P3 and the direction of extension of the same one row of the first sub-pixels P1 is substantially 15°.

In at least one embodiment of the present application, as shown in FIGS. 3, 6 and 10, the first virtual tetragon A1A2A3A4 is a rectangle, and the area of the virtual triangle A1B2B3 is less than a half of the area of the first virtual tetragon A1A2A3A4.

For example, the area of the virtual triangle A1B2B3 is substantially equal to ¼ of the area of the first virtual tetragon A1A2A3A4.

In an exemplary embodiment, the displaying base board is an OLED displaying base board, each of the sub-pixels of the displaying base board comprises a light filtering layer (CF, Color Filter) located on the side of the OLED luminescent layer (EML) that is farther from the substrate, and the light filtering layer (CF, Color Filter) is integrated at the packaging layer. Such a technique is referred to as the COE (Color on Encapsulation) technique.

As an example, the light filtering layer may comprise a first light filtering pattern, a second light filtering pattern and a third light filtering pattern. The orthographic projection of the first light filtering pattern on the substrate of the displaying base board and the orthographic projection of a first pixel unit P1 on the substrate intersect or overlap, the orthographic projection of the second light filtering pattern on the substrate and the orthographic projection of a second pixel unit on the substrate intersect or overlap, and the orthographic projection of the third light filtering pattern on the substrate and the orthographic projection of a third pixel unit on the substrate intersect or overlap.

In addition, in some embodiments, in order to increase the light rays and increase the color gamut, it is configured that the orthographic projections of the light filtering patterns on the substrate cover the orthographic projections of the pixel opening regions of the sub-pixels on the substrate.

The “covering” may be understood as that the areas of the orthographic projections of the light filtering patterns on the substrate are greater than or equal to the areas of the orthographic projections of the pixel opening regions of the sub-pixels on the substrate.

For example, it is configured that the orthographic projection of the first light filtering pattern on the substrate covers the orthographic projection of the pixel opening region of the first sub-pixel on the substrate, it is configured that the orthographic projection of the second light filtering pattern on the substrate covers the orthographic projection of the pixel opening region of the second sub-pixel on the substrate, and it is configured that the orthographic projection of the third light filtering pattern on the substrate covers the orthographic projection of the pixel opening region of the third sub-pixel on the substrate.

In some embodiments, it may be configured that, within at least part of the region of the displaying base board, the shapes of the patterns of the orthographic projections of the light filtering patterns on the substrate are the same as the shapes of the patterns of the orthographic projections of the pixel opening regions of the sub-pixels on the substrate, so that the effects of light filtering by the light filtering patterns to the light rays emitted by the sub-pixels are the same at different visual angles, to prevent color deviation at the different visual angles, thereby improving the effect of displaying.

As an example, the shape of the pattern of the orthographic projection of the first light filtering pattern on the substrate is the same as the shape of the pattern of the orthographic projection of the pixel opening region of the first sub-pixel P1 on the substrate.

As an example, the shape of the pattern of the orthographic projection of the second light filtering pattern on the substrate is the same as the shape of the pattern of the orthographic projection of the pixel opening region of the second sub-pixel P2 on the substrate.

As an example, the shape of the pattern of the orthographic projection of the third light filtering pattern on the substrate is the same as the shape of the pattern of the orthographic projection of the pixel opening region of the third sub-pixel P3 on the substrate.

Regarding the OLED displaying base boards using the technique of COE, external light rays (for example, the ambient light) are easily reflected, which causes that the display panel fabricated by using the displaying base board has chaotic color separation, to affect the effect of displaying.

The reason for the color separation will be explained below. When the display panel is in the extinguishing state, the external light rays emit white-color light beams to the display panel having a plurality of green-color sub-pixels and a plurality of red-color sub-pixels, the plurality of green-color sub-pixels form a green-color pixel matrix having a reflecting face, and the reflecting face is not parallel to the reflecting face of the red-color pixel matrix formed by the plurality of red-color sub-pixels. The non-parallel pixel matrix may be attributed to various processes, wherein the processes include but are not limited to processes of fabricating the display panel and processes of curving the display panel. The ambient light beams reflected by the elements and the metal traces of the display panel are transmitted out of the display panel via different color filtering layers corresponding to the different sub-pixels, so that the ambient light beams reflected out of the display panel can display different colors according to the different light filtering layers (CF, Color Filter) that transmit the ambient light beams. When the reflected ambient light beams are transmitted via one of the plurality of green-color sub-pixels, the reflected ambient light beams change into green-color reflected ambient light beams. When the reflected ambient light beams are transmitted via one of the plurality of red-color sub-pixels, the reflected ambient light beams change into red-color reflected ambient light beams. Because the reflecting face of the green-color pixel matrix and the reflecting face of the red-color pixel matrix are not parallel, the plurality of green-color reflected ambient light beams are transmitted in a direction deviating from the transmission direction of the plurality of red-color reflected ambient light beams, and the human eyes see a green-color light-source image and a red-color light-source image (for example, color separation), which causes color separation.

Regarding the display panel of the COE technique, the light rays emitted by the luminescent layer, when passing through the light filtering layer and exiting, are diffracted to a certain extent, which diffraction aggravates the color separation.

When the planar shape of the same one sub-pixel has a high difference in different directions, the diffractions in different directions in the same one sub-pixel might be different due to the dimension difference in the different directions. As compared with the polygonal sub-pixels, the diffraction of the sub-pixels of the shapes of an arc shape or the combination of a polygon and an arc shape is much slighter, which alleviates the color separation.

In an exemplary embodiment, it may be configured that, in the same one sub-pixel, the dimension difference from the geometric center of the planar pattern of that sub-pixel pointing to the edges is less than or equal to a preset value, wherein the preset value is less than or equal to 0.2 μm, or the preset value is less than or equal to 0.1 μm.

In an exemplary embodiment, it may be configured that, in the same one sub-pixel, the difference between the dimension of the planar pattern of that sub-pixel in the first direction (for example, the direction OA, or the direction of extension of the same one column of the first sub-pixels P1) and the dimension in the second direction (for example, the direction OB, or the direction of extension of the same one row of the first sub-pixels P1) is less than or equal to 0.1 μm.

As an example, the planar pattern of that sub-pixel may be a circle or a rounded-corner square.

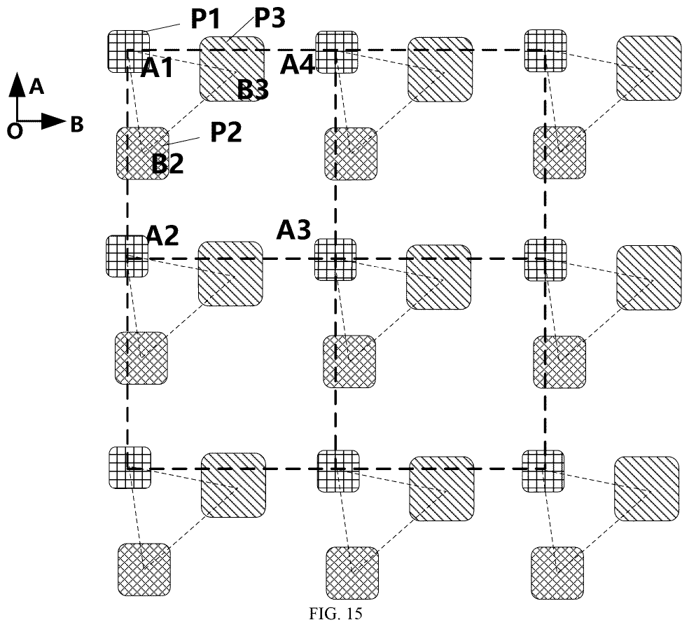

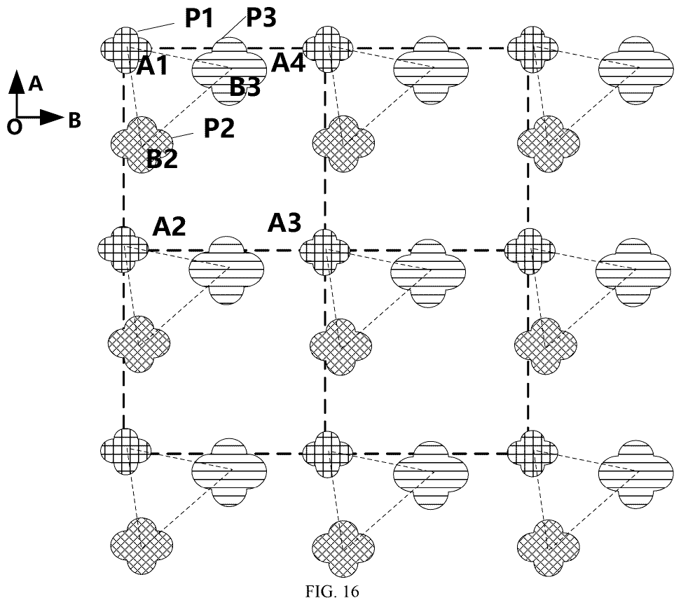

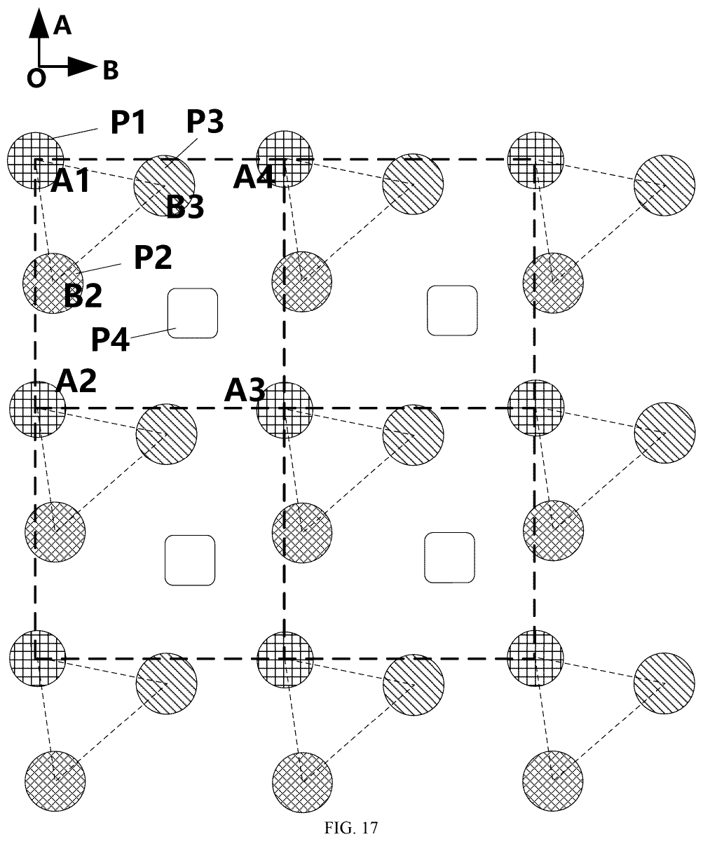

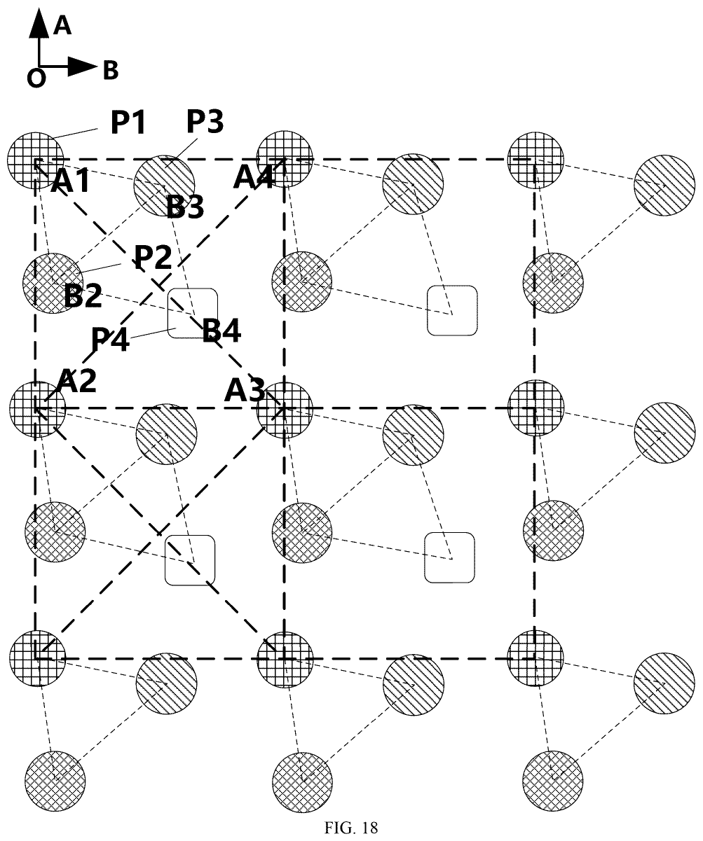

As an example, as shown in FIG. 15, FIG. 15 provides a schematic planar structural diagram of a displaying base board in which the planar pattern of the sub-pixels is a rounded-corner rectangle. As shown in FIG. 16, FIG. 16 provides a schematic planar structural diagram of a displaying base board in which the planar pattern of the sub-pixels is an are shape (a petal shape or a petal-like shape). It should be noted that all of FIGS. 3-14 according to the embodiments of the present application illustrate by taking the case as an example in which the planar patterns of the sub-pixels are circles, which does not represent limitation on the planar patterns of the sub-pixels according to the present application.

In the displaying base board according to the embodiments of the present application, it may be configured that the shapes of at least some of the first sub-pixels P1, the second sub-pixels P2 and the third sub-pixels P3 comprise an are shape and a combination of a polygon and an are shape, for example, the rounded-comer rectangular sub-pixels shown in FIG. 11 and the circular sub-pixels shown in FIG. 10, and, as another example, the sub-pixels of the symmetrical arc-shaped patterns shown in FIG. 12. Accordingly, the diffractions of the same one sub-pixel in various directions can tend to be the same, which can significantly ameliorate the problem of color separation, to improve the effect of displaying.

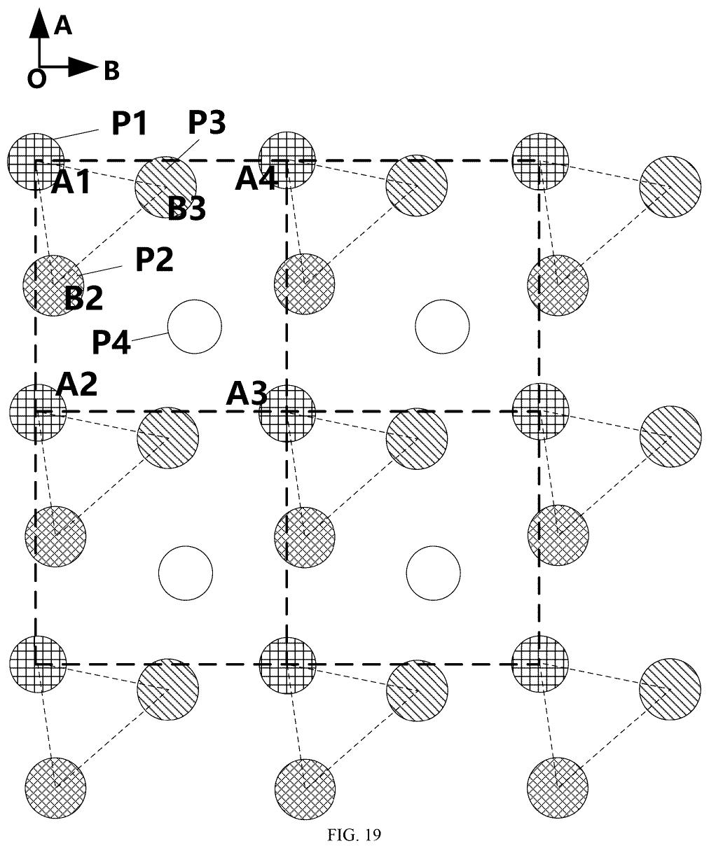

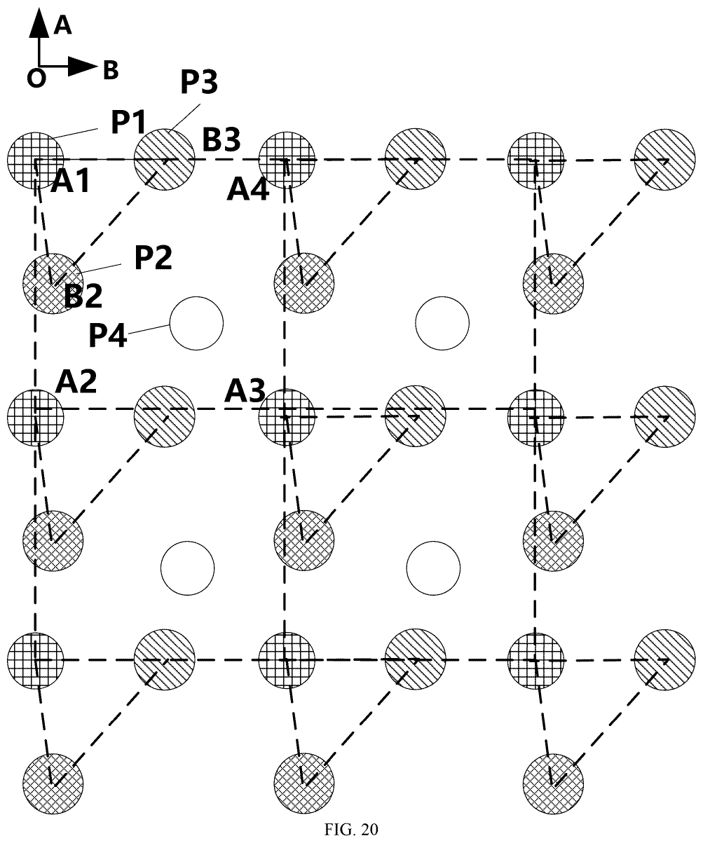

In at least one embodiment of the present application, as shown in FIGS. 17-22, each of at least some of the pixel units further comprises a fourth sub-pixel P4. As shown in FIG. 18, the first sub-pixel P1, the second sub-pixel P2, the third sub-pixel P3 and the fourth sub-pixel P4 are sequentially located at the four vertex positions of a second virtual tetragon A1B2B4B3, the second virtual tetragon A1B2B4B3 is located within the first virtual tetragon A1A2A3A4, and two lateral sides of the second virtual tetragon A1B2B4B3 are shared with two lateral sides of the virtual triangle A1B2B3.

As shown in FIGS. 17-22, the fourth sub-pixel P4 is a light transmitting component, and

the orthographic projection of the fourth sub-pixel P4 on the substrate and the orthographic projection of at least one diagonal line (for example, the diagonal line A1A3 or the diagonal line A2A4) of the first virtual tetragon A1A2A3A4 on the substrate have an overlapping part.

As an example, the orthographic projection of the fourth sub-pixel P4 on the substrate and the orthographic projection of the diagonal line A1A3 of the first virtual tetragon A1A2A3A4 on the substrate have an overlapping part.

As an example, the orthographic projection of the fourth sub-pixel P4 on the substrate and the orthographic projection of the diagonal line A2A4 of the first virtual tetragon A1A2A3A4 on the substrate have an overlapping part.

As an example, the orthographic projection of the fourth sub-pixel P4 on the substrate

bas an overlapping part with both of the orthographic projections of the diagonal line A1A3 and the diagonal line A2A4 of the first virtual tetragon A1A2A3A4 on the substrate.

It should be noted that the fourth sub-pixel P4 is not a real sub-pixel that is used to emit the displaying light rays, and, in the present application, in order to facilitate to describe the position and the distribution rule of the light transmitting component, it is named as the fourth sub-pixel P4. That the fourth sub-pixel P4 is a light transmitting component may include the following cases:

In the first case, within the region where the fourth sub-pixel P4 is located, there is not provided a light emitting device, and not provided the pixel driving circuit for driving a light emitting device to emit light, and the light transmitting component may comprise a hollowed-out part. In other words, the region where the fourth sub-pixel P4 is located is a hollowed-out part.

In the second case, within the region where the fourth sub-pixel P4 is located, there is not provided a light emitting device, and not provided the pixel driving circuit for driving a light emitting device to emit light, and each of the film layers within the region where the fourth sub-pixel P4 is located in the displaying base board is a light transmitting film layer. In other words, within the region where the fourth sub-pixel P4 is located, there is merely provided a light transmitting material.

As an example, the material of the light transmitting film layers comprises one or more of silicon oxide, silicon nitride, silicon oxynitride, polyimide, acrylic resin, polyethylene terephthalate (PET), polycarbonate (PC), epoxy resin and another transparent material. The light transmitting film layers may include the insulating layers between the electrically conducting film layers of the pixel driving circuits, may also include some of the functional layers in the light emitting devices, and may also include the packaging layer or the other functional film layers. In this case, the displaying base board may be used to fabricate transparent displaying devices in which at least part of the region is transparent.

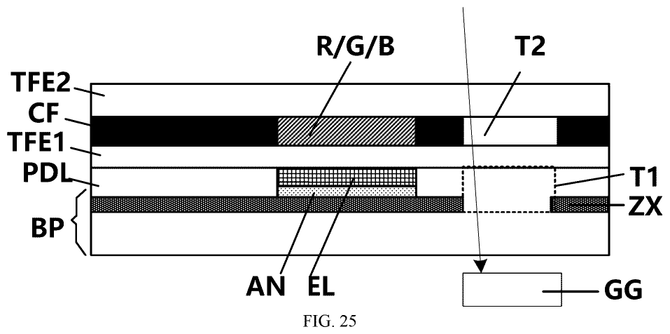

Alternatively, as shown in FIG. 25, a light sensing device GG may be provided under the region where the fourth sub-pixel P4 is located in the displaying base board (the side of the substrate that is farther from the light emitting device), for example, a fingerprint sensor, an optical sensor or a camera, so as to fabricate displaying devices that integrate multiple functions of the fingerprint sensor, the optical sensor and the camera.

In an exemplary embodiment, in the sub-pixel queues (including sub-pixel columns or sub-pixel rows) formed by a plurality of fourth sub-pixels P4 (which are the fourth sub-pixels within the regions corresponding to the light sensing devices according to some of the embodiments), the connecting lines of the centers of the fourth sub-pixels P4 may be straight lines.

In an exemplary embodiment, regarding the same one row of the fourth sub-pixels P4, the connecting line of the centers of the fourth sub-pixels P4 is substantially parallel to the connecting line of the centers of the same one row of the third sub-pixels P3.

In an exemplary embodiment, regarding the same one column of the fourth sub-pixels P4, the connecting line of the centers of the fourth sub-pixels P4 is substantially parallel to the connecting line of the centers of the same one column of the second sub-pixels P2.

In an exemplary embodiment, as shown in FIG. 18, in a sub-pixel row formed by a plurality of second sub-pixels P2 and a plurality of fourth sub-pixels P4, the connecting line of the centers of the sub-pixels is a folding line, and the folding line is substantially parallel to the connecting line of the centers of the sub-pixels in a sub-pixel row formed by a plurality of first sub-pixels P1 and a plurality of third sub-pixels P3.

In an exemplary embodiment, in a sub-pixel column formed by a plurality of first sub-pixels P1 and a plurality of second sub-pixels P2, the connecting line of the centers of the sub-pixels is a folding line, and the folding line is substantially parallel to the connecting line of the centers of the sub-pixels in a sub-pixel column formed by a plurality of third sub-pixels P3 and a plurality of fourth sub-pixels P4.

As an example, in a sub-pixel column formed by a plurality of third sub-pixels P3 and a plurality of fourth sub-pixels P4, each of the fourth sub-pixels P4 is located between two neighboring third sub-pixels P3, and the distances between the geometric center of the fourth sub-pixel P4 and the geometric centers of the two third sub-pixels P3 are substantially equal. The two neighboring third sub-pixels P3 refer to that, between the two third sub-pixels P3, no other third sub-pixel P3 is provided.

As an example, in a sub-pixel row formed by a plurality of second sub-pixels P2 and a plurality of fourth sub-pixels P4, each of the fourth sub-pixels P4 is located between two neighboring second sub-pixels P2, and the distances between the geometric center of the fourth sub-pixel P4 and the geometric centers of the two second sub-pixels P2 are substantially equal. The two neighboring second sub-pixels P2 refer to that, between the two second sub-pixels P2, no other second sub-pixel P2 is provided.

In the embodiments of the present application, by configuring that each of at least some of the pixel units further comprises a fourth sub-pixel P4, the first sub-pixel P1, the second sub-pixel P2, the third sub-pixel P3 and the fourth sub-pixel P4 are sequentially located at the four vertex positions of a second virtual tetragon A1B2B4B3, the second virtual tetragon A1B2B4B3 is located within the first virtual tetragon A1A2A3A4, and the fourth sub-pixel P4 is a light transmitting component, in an aspect, the problem in the related art of the color mixing caused by the film-layer overlapping between two sub-pixels arranged in the linear-source distribution direction can be ameliorated, which improves the effect of displaying of the displaying base board to a large extent. In another aspect, while the sizes of the pixel openings of the sub-pixels are maintained constant, the spacing (Gap) between two neighboring sub-pixels can be increased, which further reduces the problem of the color mixing caused by the film-layer overlapping between two sub-pixels. In yet another aspect, while the spacing (Gap) between two neighboring sub-pixels is maintained constant, more design room can be used to increase the pixel openings (for example, increasing the areas of the anodes of the sub-pixels), thereby increasing the aperture ratio, to increase the light transmittance and the optical efficiency of the display panel. In still another aspect, that can expand the application scope of the displaying base board, so that it can be applied in transparent displaying devices and displaying devices that are provided with a fingerprint sensor or optical sensor.

In at least one embodiment of the present application, as shown in FIG. 18, in the same one pixel unit, the distance B4B2 between the center of the fourth sub-pixel P4 and the center of the second sub-pixel P2 and the distance B4B3 between the center of the fourth sub-pixel P4 and the center of the third sub-pixel P3 are substantially equal.

In the displaying base board according to the embodiments of the present application, by configuring that, in the same one pixel unit, the distance B4B2 between the center of the fourth sub-pixel P4 and the center of the second sub-pixel P2 and the distance B4B3 between the center of the fourth sub-pixel P4 and the center of the third sub-pixel P3 are substantially equal, because the fourth sub-pixel P4 is a light transmitting component, when the displaying base board is used to fabricate a transparent displaying device, that can increase the evenness of the distribution of the light transmitting regions in the transparent displaying device, to prevent nonuniform light transmission from interfering the normal displaying of the displayed frame, which can improve the uniformity of the displaying brightness of the transparent displaying device, thereby improving the effect of displaying.

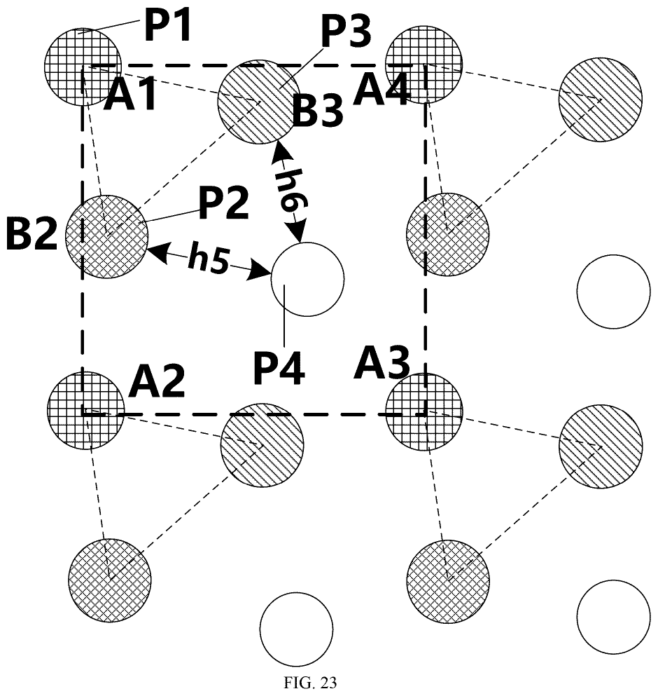

In at least one embodiment of the present application, as shown in FIG. 23, in the same one pixel unit, the minimum distance h5 between the edge of the fourth sub-pixel P4 and the edge of the second sub-pixel P2 and the minimum distance ho between the edge of the fourth sub-pixel P4 and the edge of the third sub-pixel P3 are substantially equal.

In the displaying base board according to the embodiments of the present application, by configuring that, in the same one pixel unit, the minimum distance h5 between the edge of the fourth sub-pixel P4 and the edge of the second sub-pixel P2 and the minimum distance h6 between the edge of the fourth sub-pixel P4 and the edge of the third sub-pixel P3 are substantially equal, when the displaying base board is used to fabricate a transparent displaying device, that can increase the evenness of the distribution of the light transmitting regions in the transparent displaying device, to prevent nonuniform light transmission from interfering the displayed frame, which can improve the uniformity of the displaying brightness of the transparent displaying device, thereby improving the effect of displaying.

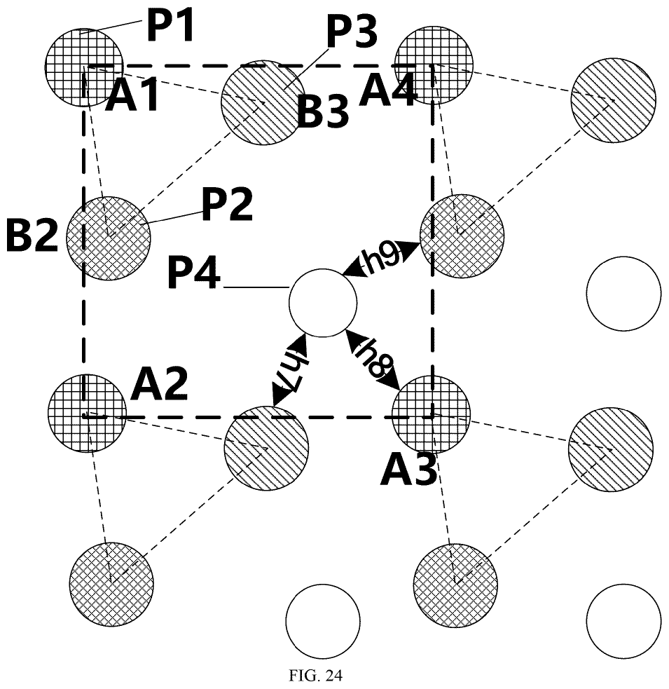

In at least one embodiment of the present application, as shown in FIG. 24, one fourth sub-pixel P4 is located among four pixel units, the four pixel units are a first pixel unit, a second pixel unit, a third pixel unit and a fourth pixel unit, the first pixel unit and the second pixel unit are arranged in the first direction (for example, the direction of extension of the same one column of the first sub-pixels), and the first pixel unit and the fourth pixel unit are arranged in the second direction (for example, the direction of extension of the same one row of the first sub-pixels).

For the fourth sub-pixel P4 in the first pixel unit, the minimum distance h7 from the edge of the fourth sub-pixel P4 to the edge of the third sub-pixel P3 in the second pixel unit, the minimum distance h8 from the fourth sub-pixel to the edge of the first sub-pixel in the third pixel unit and the minimum distance h9 from the fourth sub-pixel P4 to the edge of the second sub-pixel P2 in the fourth pixel unit are substantially equal.

In the displaying base board according to the embodiments of the present application, by configuring that, for the fourth sub-pixel P4 in the first pixel unit, the minimum distance h7 between the edge of the fourth sub-pixel P4 and the edge of the third sub-pixel P3 in the second pixel unit, the minimum distance h8 between the fourth sub-pixel and the edge of the first sub-pixel in the third pixel unit and the minimum distance h9 between the fourth sub-pixel P4 and the edge of the second sub-pixel P2 in the fourth pixel unit are substantially equal, when the displaying base board is used to fabricate a transparent displaying device, that can increase the evenness of the distribution of the light transmitting regions in the transparent displaying device, to prevent nonuniform light transmission from interfering the displayed frame, which can improve the uniformity of the displaying brightness of the transparent displaying device, thereby improving the effect of displaying.

In at least one embodiment of the present application, as shown in FIG. 18, the first virtual tetragon A1A2A3A4 comprises a first diagonal line A1A3 and a second diagonal line A2A4, and the first vertex A1 is located in the first diagonal line A1A3. At least a half of the region of the fourth sub-pixel P4 is located on the side of the second diagonal line A2A4 that is farther from the first vertex A1.

In an exemplary embodiment, the whole of the fourth sub-pixel P4 is located on the side of the second diagonal line A2A4 that is farther from the first vertex A1.

It should be noted that two neighboring first virtual tetragons may share one lateral side.

In at least one embodiment of the present application, as shown in FIG. 25, the fourth sub-pixel P4 is configured to expose the region where a light sensing device GG is provided, and the light sensing device GG is located on the shadow side of the displaying base board.

The displaying base board comprises a trace layer ZX located on the substrate, the trace layer ZX comprises a plurality of traces, and the orthographic projections of the traces on the substrate do not overlap with the orthographic projection of the fourth sub-pixel P4 on the substrate.

As an example, the displaying base board may comprise a back panel BP, the back panel BP comprises the trace layer ZX and a plurality of anodes AN, the trace layer ZX comprises a plurality of electrically conducting sublayers, and a driving circuit is provided in the trace layer ZX. The pixel defining layer PDL covers the back panel BP, the pixel opening regions in the pixel defining layer PDL expose the anodes AN, a luminescence functional layer EL is provided on the side of the anode AN that is farther from the back panel BP, the luminescence functional layer EL contacts the anode AN, and a cathode covers the luminescence functional layer EL of each of the sub-pixels. The fourth sub-pixel P4 is not provided with a light emitting device; in other words, the region where the fourth sub-pixel P4 is located is the light transmitting component T1, and the corresponding position of the back panel BP is also light-transmitting. Therefore, the distances between at least some of the sub-pixels located in the different pixel units encircling the fourth sub-pixel P4 are greater than the distances between the sub-pixels in the same one pixel unit, to ensure that, between the pixel units, there is a large area that can be configured as a light transmitting component. In some examples, the fourth sub-pixel P4 is located within the region that is encircled by the same one row of two neighboring pixel units and the next one row of two neighboring pixel units. In some examples, in one virtual tetragon, all of the first sub-pixel, the second sub-pixel and the third sub-pixel are located on the same one side of one diagonal line of the virtual tetragon, so that, in the virtual tetragon, at least the part on the other side of that diagonal line can have a large light transmitting region.

In some embodiments, the displaying base board further comprises a light filtering layer (CF, Color Filter), and the light filtering layer (CF, Color Filter) is integrated at the packaging layer. As shown in FIG. 25, the light filtering layer is provided between a first packaging sublayer TFE1 and a second packaging sublayer TFE2. The light filtering layer comprises a color-film pattern. The region of the light filtering layer that corresponds to the fourth sub-pixels P4 may be hollowed out or be filled with a light transmitting material (the region labeled T2).

As an example, the light sensing device GG may comprise at least one of a fingerprint sensor, a light sensing sensor and a camera.

When the light sensing device GG comprises a fingerprint sensor, the displaying device fabricated by using the displaying base board has the function of fingerprint identification, for example, fingerprint unlocking.

When the light sensing device GG comprises a light sensing sensor, the displaying device

fabricated by using the displaying base board has the function of automatic light regulation. For example, the light sensing sensor collects a brightness signal of the ambient light, and transmits into the circuit board of the displaying device, and the circuit board, according to the received brightness signal of the ambient light, automatically regulates the displaying brightness of the displaying device.

In at least one embodiment of the present application, the shapes of the planar patterns of the first sub-pixel P1, the second sub-pixel P2, the third sub-pixel P3 and the fourth sub-pixel P4 are at least partially the same. Each of the planar patterns of the first sub-pixel P1, the second sub-pixel P2, the third sub-pixel P3 and the fourth sub-pixel P4 comprises an are shape or a combination of an arc shape and a polygon.

That the shapes of the planar patterns of the first sub-pixel P1, the second sub-pixel P2, the third sub-pixel P3 and the fourth sub-pixel P4 are at least partially the same includes but is not limited to the following cases:

In the first case, the shapes of the planar patterns of the first sub-pixel P1, the second sub-pixel P2 and the third sub-pixel P3 are the same.

In the second case, the shapes of the planar patterns of the first sub-pixel P1 and the third sub-pixel P3 are the same.

In the third case, the shapes of the planar patterns of the first sub-pixel P1 and the second sub-pixel P2 are the same.

In the fourth case, the shapes of the planar patterns of the fourth sub-pixel P4 and the third sub-pixel P3 are the same.

In the fifth case, the shapes of the planar patterns of the fourth sub-pixel P4 and the second sub-pixel P2 are the same.

In the sixth case, the shapes of the planar patterns of the first sub-pixel P1 and the fourth sub-pixel P4 are the same.

In the seventh case, all of the shapes of the planar patterns of the first sub-pixel P1, the second sub-pixel P2, the third sub-pixel P3 and the fourth sub-pixel P4 are the same.

An embodiment of the present application provides a display panel, wherein the display panel comprises the displaying base board stated above.

The structure of the displaying base board may refer to the description in the preceding context, and is not discussed further herein.

The display panel may be a flexible display panel (i.e., bendable and foldable), or the display panel may be a rigid display panel.

The type of the display panel is not limited herein. It may be an OLED (Organic Light Emitting Diode) display panel. The OLED display panel has the advantages such as a simple fabricating process, a low cost, a low power consumption, a high emitted-light brightness, a wide range of suitable operating temperature, a low volume, a high response speed, easy color displaying, and large-screen displaying, considering a broad prospect in the applications.

Each of the sub-pixels of the displaying base board according to the above embodiments may further comprise an anode. If the anodes are formed by using a non-transparent material, then the displaying base board may be used in top-emission-type OLED display panels, or used in top-emission-type WOLED display panels, wherein the top-emission-type OLED display panels refer to the display panels in which the light rays exit from the cathode side. If the anodes are formed by using a transparent material, and the cathodes are formed by using a non-transparent material, then the OLED base board may be used in bottom-emission-type OLED display panels, wherein the bottom-emission-type OLED display panels refer to the display panels in which the light rays exit from the anode side.

In the display panel according to the embodiments of the present application, in the practical vapor-deposition process, when the linear-source distribution direction is the same as the first direction, and the linear-source vapor-deposition scanning direction is the same as the second direction, the connecting line between the center of the first sub-pixel and the center of the second sub-pixel (the third sub-pixel) has an included angle with at least one of the first direction and the second direction, and both of more than a half of the region of the second sub-pixel P2 and at least a half of the region of the third sub-pixel P3 in the same one pixel unit are located on the same one side of the connecting line of the centers of the same one queue of the first sub-pixels P1. Accordingly, in an aspect, the problem in the related art of the color mixing caused by the film-layer overlapping between two sub-pixels arranged in the linear-source distribution direction can be ameliorated, which improves the effect of displaying of the displaying base board to a large extent. In another aspect, while the sizes of the pixel openings of the sub-pixels are maintained constant, the spacing (Gap) between two neighboring sub-pixels can be increased, which further reduces the problem of the color mixing caused by the film-layer overlapping between two sub-pixels. In yet another aspect, while the spacing (Gap) between two neighboring sub-pixels is maintained constant, more design room can be used to increase the pixel openings (for example, increasing the areas of the anodes of the sub-pixels), thereby increasing the aperture ratio, to increase the light transmittance and the optical efficiency of the display panel.

An embodiment of the present application provides a displaying device, wherein the displaying device comprises the display panel stated above.

The displaying device may be a displaying device such as an OLED display, and any product or component having the function of displaying and comprising the displaying device, such as a television set, a digital camera, a mobile phone, a tablet personal computer and an onboard display screen.

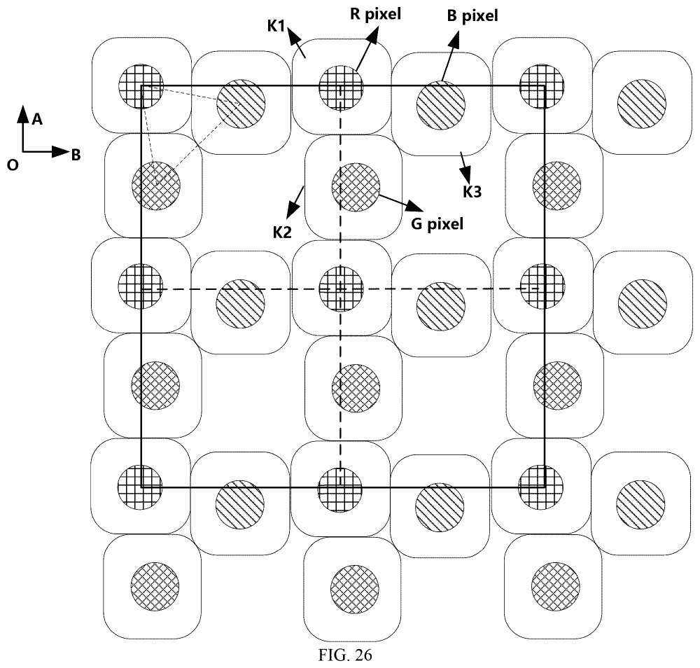

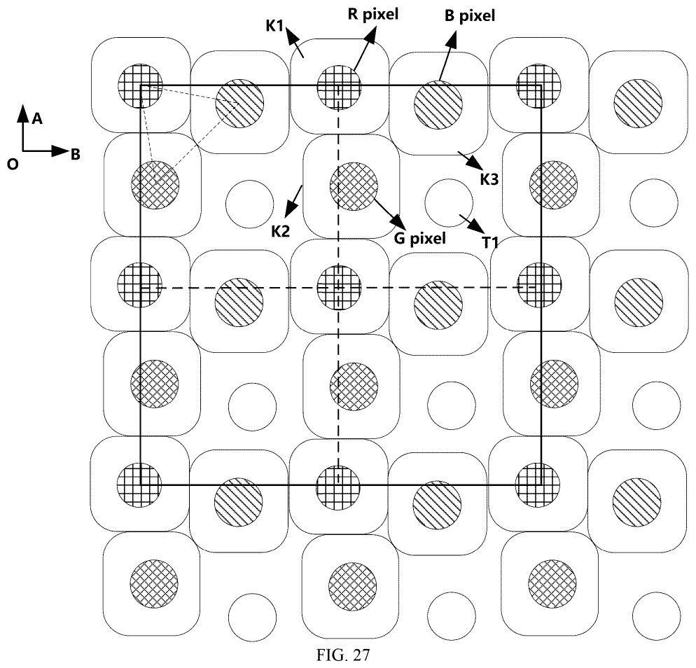

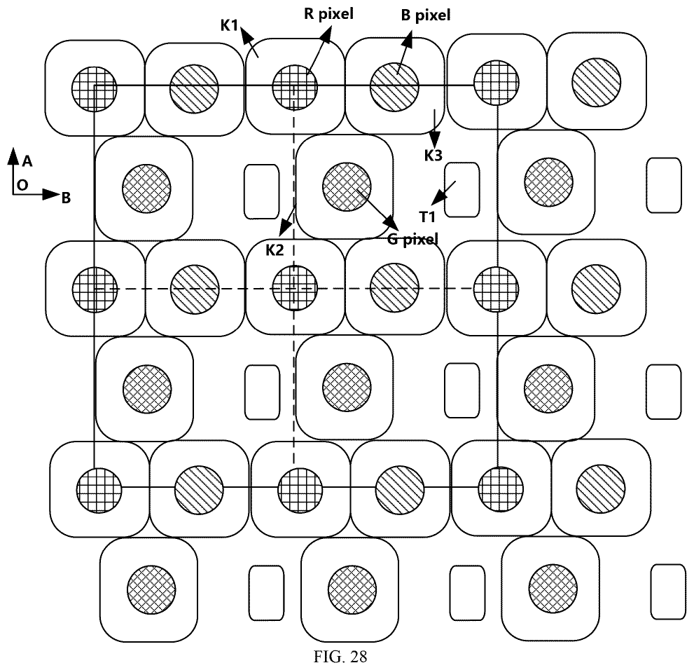

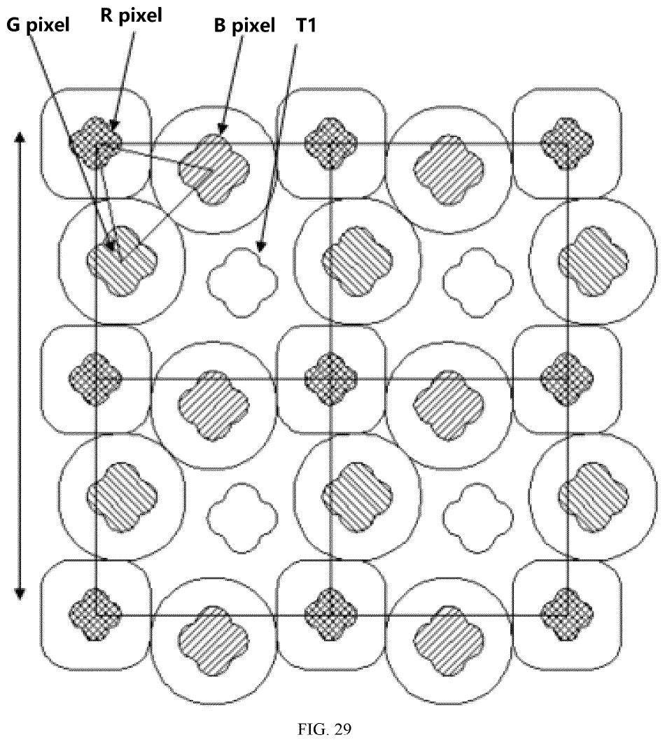

An embodiment of the present application provides a mask group, wherein the mask group is applied to fabricate the displaying base board stated above. FIGS. 26-29 provide planar structural diagrams when the mask group and the sub-pixels have been superposed together. Referring to FIGS. 26-29, the mask group comprises:
a first mask comprising a plurality of first openings K1, wherein the first openings K1 are configured for forming luminescent layers of the first sub-pixels P1;
a second mask comprising a plurality of second openings K2, wherein the second openings K2 are configured for forming luminescent layers of the second sub-pixels P2; and
a third mask comprising a plurality of third openings K3, wherein the third openings K3 are configured for forming luminescent layers of the third sub-pixels P3.

The mask group comprises opening groups, and each of the opening groups comprises one first opening K1, one second opening K2 and one third opening K3. In the same one opening group, the connecting lines between the orthographic projection of the outer contour of the second opening K2 on the first mask, the orthographic projection of the outer contour of the third opening K3 on the first mask and the center of the outer contour of the first opening K1 form an acute triangle.

The connecting line between the center of the orthographic projection of the outer contour of the second opening K2 on the first mask and the center of the outer contour of the first opening K1 has an included angle with the net-deployment stretching direction (for example, the direction OA or the vertical direction pointed by the arrows shown in FIG. 29) of the masks.

It should be noted that, in the description, the descriptions on “having an included angle” refer to that the included angle is not 0°.

It should also be noted that FIGS. 26-29 provide planar structural diagrams when the mask group and the sub-pixels have been superposed together. From another perspective, the contours labeled as the first opening K1, the second opening K2 and the third opening K3 in FIGS. 26-29 may also be deemed as top views when the luminescent layer of the first sub-pixel P1, the luminescent layer of the second sub-pixel P2 and the luminescent layer of the third sub-pixel P3 are tangent.

As an example, the angle between the connecting line between the center of the orthographic projection of the outer contour of the second opening K2 on the first mask and the center of the outer contour of the first opening K1 and the net-deployment stretching direction of the masks is 10°, 17°, 25° or 30°.

As an example, the interior angles of the triangle formed by the connecting lines between the centers of the sub-pixels are 65°, 57.5° and 57.5°, and one side of the triangle (the connecting line between the center of the first sub-pixel P1 and the center of the second sub-pixel P2 or the connecting line between the center of the first opening K1 and the center of the second opening K2) has an included angle with the net-deployment stretching direction of 12°.

As an example, the interior angles of the triangle formed by the connecting lines between the centers of the sub-pixels are 62°, 53° and 65°, and one side of the triangle (the connecting line between the center of the first sub-pixel P1 and the center of the second sub-pixel P2 or the connecting line between the center of the first opening K1 and the center of the second opening K2) has an included angle with the net-deployment stretching direction of 28°.

As an example, the interior angles of the triangle formed by the connecting lines between the centers of the sub-pixels are 68°, 56° and 56°, and one side of the triangle (the connecting line between the center of the first sub-pixel P1 and the center of the second sub-pixel P2 or the connecting line between the center of the first opening K1 and the center of the second opening K2) has an included angle with the net-deployment stretching direction of 10°.

As an example, the direction of extension of the connecting line between the center of the orthographic projection of the outer contour of the third opening K3 on the first mask and the center of the outer contour of the first opening K1 is the same as the vapor-deposition scanning direction.

The net-deployment stretching direction of the masks is the direction of extension of the same one column of the first sub-pixels P1. Alternatively, the net-deployment stretching direction of the masks is the direction of extension of the same one column of the first openings K1.

In at least one embodiment of the present application, the connecting line between the center of the orthographic projection of the outer contour of the third opening K3 on the first mask and the center of the outer contour of the first opening K1 has an included angle with the vapor-deposition scanning direction.

The vapor-deposition scanning direction is the direction of extension of the same one row of the first sub-pixels P1. Alternatively, the net-deployment stretching direction of the masks is the direction of extension of the same one row of the first openings K1.

In the mask group according to the embodiments of the present application, in the practical vapor-deposition process, when the linear-source distribution direction is the same as the first direction, and the linear-source vapor-deposition scanning direction is the same as the second direction, the connecting line between the center of the first sub-pixel P1 and the center of the second sub-pixel P2 (the third sub-pixel P3) has an included angle with at least one of the first direction and the second direction, and both of more than a half of the region of the second sub-pixel P2 and at least a half of the region of the third sub-pixel P3 in the same one pixel unit are located on the same one side of the connecting line of the centers of the same one queue of the first sub-pixels P1. The connecting line between the center of the orthographic projection of the outer contour of the second opening K2 on the first mask and the center of the outer contour of the first opening K1 has an included angle with the net-deployment stretching direction of the masks. In at least one embodiment of the present application, the connecting line between the center of the orthographic projection of the outer contour of the third opening K3 on the first mask and the center of the outer contour of the first opening K1 has an included angle with the vapor-deposition scanning direction. By using the displaying base board fabricated by using the mask group, in an aspect, the problem in the related art of the color mixing caused by the film-layer overlapping between two sub-pixels arranged in the linear-source distribution direction can be ameliorated, which improves the effect of displaying of the displaying base board to a large extent. In another aspect, while the sizes of the pixel openings of the sub-pixels are maintained constant, the spacing (Gap) between two neighboring sub-pixels can be increased, which further reduces the problem of the color mixing caused by the film-layer overlapping between two sub-pixels. In yet another aspect, while the spacing (Gap) between two neighboring sub-pixels is maintained constant, more design room can be used to increase the pixel openings (for example, increasing the areas of the anodes of the sub-pixels), thereby increasing the aperture ratio, to increase the light transmittance and the optical efficiency of the displaying base board. In still another aspect, in the process of fabricating the displaying base board by using the mask group, the processes of net deployment and vapor deposition have a low difficulty and a high fabrication yield.

In at least one embodiment of the present application, the orthographic projection of the outer contour of the second opening K2 on the first mask and the orthographic projection of the outer contour of the third opening K3 on the first mask are tangent to the outer contour of the first opening K1, and the orthographic projection of the outer contour of the second opening K2 on the first mask and the orthographic projection of the outer contour of the third opening K3 on the first mask are tangent to each other.

In at least one embodiment of the present application, the included angle between the connecting line between the center of the orthographic projection of the outer contour of the second opening K2 on the first mask and the center of the outer contour of the first opening K1 and the net-deployment stretching direction of the masks is greater than 0° and less than or equal to 30°.

As an example, the included angle between the connecting line between the center of the orthographic projection of the outer contour of the second opening K2 on the first mask and the center of the outer contour of the first opening K1 and the net-deployment stretching direction of the masks may be 1°, 3°, 5°, 6°, 7°, 8°, 9°, 10°, 11°, 12°, 13°, 14°, 15°, 16″, 17°, 18°, 19°, 20°, 21°, 22°, 23°, 24°, 25°, 26°, 27°, 28° and 29°.

In at least one embodiment of the present application, the included angle between the connecting line between the center of the orthographic projection of the outer contour of the third opening K3 on the first mask and the center of the outer contour of the first opening K1 and the vapor-deposition scanning direction is greater than 0° and less than or equal to 30°.

As an example, the included angle between the connecting line between the center of the orthographic projection of the outer contour of the third opening K3 on the first mask and the center of the outer contour of the first opening K1 and the vapor-deposition scanning direction may be 10, 3°, 5°, 6″, 7°, 8°, 99, 10°, 11°, 12°, 13″, 14°, 15°, 16°, 17°, 18°, 19°, 20°, 21°, 22″, 23°, 24°, 25°, 26°, 27°, 28° and 29°.

It is not limited herein whether the included angle between the connecting line between the center of the orthographic projection of the outer contour of the second opening K2 on the first mask and the center of the outer contour of the first opening K1 and the net-deployment stretching direction of the masks and the included angle between the connecting line between the center of the orthographic projection of the outer contour of the third opening K3 on the first mask and the center of the outer contour of the first opening K1 and the vapor-deposition scanning direction are equal.

In some embodiments, in order to take into consideration both of the distance between the first sub-pixel P1 and the second sub-pixel P2 and the distance between the first sub-pixel P1 and the third sub-pixel P3 in the displaying base board fabricated by using the mask group, to reduce at the same time the probability in color mixing between the first sub-pixel P1 and the second sub-pixel P2 and the probability in color mixing between the first sub-pixel P1 and the third sub-pixel P3, it may be configured that the included angle between the connecting line between the center of the orthographic projection of the outer contour of the second opening K2 on the first mask and the center of the outer contour of the first opening K1 and the net-deployment stretching direction of the masks and the included angle between the connecting line between the center of the orthographic projection of the outer contour of the third opening K3 on the first mask and the center of the outer contour of the first opening K1 and the vapor-deposition scanning direction are substantially equal.

The above are merely particular embodiments of the present application, and the protection scope of the present application is not limited thereto. All of the variations or substitutions that a person skilled in the art can easily envisage within the technical scope disclosed by the present application should fall within the protection scope of the present application. Therefore, the protection scope of the present application should be subject to the protection scope of the claims.

1. A displaying base board, wherein the displaying base board comprises a substrate and a plurality of pixel units that are located on the substrate and are arranged in an array, and each of at least some of the pixel units comprises a first sub-pixel, a second sub-pixel and a third sub-pixel;
a center of the first sub-pixel, a center of the second sub-pixel and a center of the third sub-pixel are sequentially located at vertex positions of a virtual triangle;
a connecting line between the center of the first sub-pixel and the center of any one of the other sub-pixels in a same one instance of the pixel units has an included angle with at least one of a first direction and a second direction, wherein each of the first direction and the second direction is a direction of extension of a same one queue of the first sub-pixels, and the first direction and the second direction intersect; and
both of more than a half of a region of the second sub-pixel and at least a half of a region of the third sub-pixel in a same one instance of the pixel units are located on a same one side of a connecting line of the centers of a same one queue of the first sub-pixels.

2. The displaying base board according to claim 1, wherein the connecting line between the center of the first sub-pixel and the center of the any one of the other sub-pixels in the same one pixel unit has included angles with both of the first direction and the second direction.

3. The displaying base board according to claim 1, wherein the connecting line between the center of the first sub-pixel and the center of the second sub-pixel in the same one pixel unit has an included angle with the first direction, wherein the first direction is a direction of extension of a same one column of the first sub-pixels.

4. The displaying base board according to claim 2, wherein four instances of the first sub-pixels are located at vertex positions of a first virtual tetragon, the virtual triangle is located within the first virtual tetragon, and the first virtual tetragon and the virtual triangle share one vertex.

5. The displaying base board according to claim 4, wherein in a same one instance of the pixel units, at least two of a distance between the center of the first sub-pixel and the center of the second sub-pixel, a distance between the center of the first sub-pixel and the center of the third sub-pixel, and a distance between the center of the second sub-pixel and the center of the third sub-pixel are substantially equal.

6. The displaying base board according to claim 5, wherein the distance between the center of the first sub-pixel and the center of the second sub-pixel and the distance between the center of the first sub-pixel and the center of the third sub-pixel are substantially equal.

7. The displaying base board according to claim 5, wherein the second direction is a direction of extension of a same one row of the first sub-pixels, the first virtual tetragon comprises a first lateral side extending in the first direction and a second lateral side extending in the second direction, the first lateral side and the second lateral side intersect at a first vertex, the first sub-pixel in the same one pixel unit is located at the first vertex, an orthographic projection of the second sub-pixel on the substrate and an orthographic projection of the first lateral side on the substrate at least partially do not overlap, and an orthographic projection of the third sub-pixel on the substrate and an orthographic projection of the second lateral side on the substrate partially overlap.

8. The displaying base board according to claim 7, wherein in one instance of the first virtual tetragon, one instance of the pixel units exists in which an area of a region of the pixel unit that is located within the first virtual tetragon is greater than an area of a region of the pixel unit that is located outside the first virtual tetragon.

9. The displaying base board according to claim 7, wherein the distance between the center of the first sub-pixel and the center of the second sub-pixel in the same one pixel unit is greater than or equal to a half of a side length of the first lateral side of the first virtual tetragon.

10. The displaying base board according to claim 7, wherein the distance between the center of the first sub-pixel and the center of the third sub-pixel in the same one pixel unit is greater than or equal to a half of a side length of the second lateral side of the first virtual tetragon.

11. The displaying base board according to claim 1, wherein in a same one instance of the pixel units, a minimum distance between an edge of the first sub-pixel and an edge of the second sub-pixel and a minimum distance between the edge of the first sub-pixel and an edge of the third sub-pixel are substantially equal.

12. The displaying base board according to claim 11, wherein the minimum distance between the edge of the third sub-pixel and the edge of the first sub-pixel in the same one pixel unit is substantially equal to a minimum distance from the edge of the third sub-pixel to an edge of the first sub-pixel in a neighboring instance of the pixel units; and
the minimum distance between the edge of the second sub-pixel and the edge of the first sub-pixel in the same one pixel unit is substantially equal to a minimum distance from the edge of the second sub-pixel to the edge of the first sub-pixel in the neighboring pixel unit; or
wherein the virtual triangle is an acute triangle, and the included angle between the connecting line between the center of the first sub-pixel and the center of the any one of the other sub-pixels in the same one pixel unit and the at least one of the first direction and the second direction is greater than 0° and less than or equal to 30°; or
wherein the first virtual tetragon is a rectangle, and an area of the virtual triangle is less than a half of an area of the first virtual tetragon.

13. (canceled)

14. The displaying base board according to claim 7, wherein an included angle between the connecting line between the center of the first sub-pixel and the center of the second sub-pixel in the same one pixel unit and a direction of extension of a same one column of the first sub-pixels is substantially equal to an included angle between the connecting line between the center of the first sub-pixel and the center of the third sub-pixel and a direction of extension of a same one row of the first sub-pixels.

15. (canceled)

16. The displaying base board according to claim 7, wherein each of at least some of the pixel units further comprises a fourth sub-pixel, the first sub-pixel, the second sub-pixel, the third sub-pixel and the fourth sub-pixel are sequentially located at four vertex positions of a second virtual tetragon, the second virtual tetragon is located within the first virtual tetragon, and two lateral sides of the second virtual tetragon are shared with two lateral sides of the virtual triangle; and
the fourth sub-pixel is a light transmitting component, and an orthographic projection of the fourth sub-pixel on the substrate and an orthographic projection of at least one diagonal line of the first virtual tetragon on the substrate have an overlapping part.

17. The displaying base board according to claim 16, wherein in a same one instance of the pixel units, a distance between a center of the fourth sub-pixel and the center of the second sub-pixel and a distance between the center of the fourth sub-pixel and the center of the third sub-pixel are substantially equal; or
wherein in a same one instance of the pixel units, a minimum distance between an edge of the fourth sub-pixel and an edge of the second sub-pixel and a minimum distance between the edge of the fourth sub-pixel and an edge of the third sub-pixel are substantially equal; or
wherein the first virtual tetragon comprises a first diagonal line and a second diagonal line, and the first vertex is located in the first diagonal line; and
at least a half of a region of the fourth sub-pixel is located on one side of the second diagonal line that is farther from the first vertex; or
wherein the fourth sub-pixel is configured to expose a region where a light sensing device is provided, and the light sensing device is located on a shadow side of the displaying base board; and
the displaying base board comprises a trace layer located on the substrate, the trace layer comprises a plurality of traces, and orthographic projections of the traces on the substrate do not overlap with an orthographic projection of the fourth sub-pixel on the substrate; or
wherein shapes of planar patterns of the first sub-pixel, the second sub-pixel, the third sub-pixel and the fourth sub-pixel are at least partially the same; and
each of the planar patterns of the first sub-pixel, the second sub-pixel, the third sub-pixel and the fourth sub-pixel comprises an are shape or a combination of an arc shape and a polygon.

18. (canceled)

19. The displaying base board according to claim 16, wherein one instance of the fourth sub-pixel is located among four instances of the pixel units, the four pixel units are a first pixel unit, a second pixel unit, a third pixel unit and a fourth pixel unit, the first pixel unit and the second pixel unit are arranged in the first direction, and the first pixel unit and the fourth pixel unit are arranged in the second direction; and
for the fourth sub-pixel in the first pixel unit, a minimum distance from an edge of the fourth sub-pixel to an edge of the third sub-pixel in the second pixel unit, a minimum distance from the fourth sub-pixel to an edge of the first sub-pixel in the third pixel unit and a minimum distance from the fourth sub-pixel to an edge of the second sub-pixel in the fourth pixel unit are substantially equal.

20. (canceled)

21. (canceled)

22. (canceled)

23. A display panel, wherein the display panel comprises the displaying base board according to claim 1.

24. A mask group, wherein the mask group is applied to fabricate the displaying base board according to claim 1;
the mask group comprises:
a first mask comprising a plurality of first openings, wherein the first openings are configured for forming luminescent layers of the first sub-pixels;
a second mask comprising a plurality of second openings, wherein the second openings are configured for forming luminescent layers of the second sub-pixels; and
a third mask comprising a plurality of third openings, wherein the third openings are configured for forming luminescent layers of the third sub-pixels;
the mask group comprises opening groups, and each of the opening groups comprises one instance of the first openings, one instance of the second openings and one instance of the third openings;
in a same one instance of the opening groups, connecting lines between an orthographic projection of an outer contour of the second opening on the first mask, an orthographic projection of an outer contour of the third opening on the first mask and a center of an outer contour of the first opening form an acute triangle; and
a connecting line between a center of the orthographic projection of the outer contour of the second opening on the first mask and the center of the outer contour of the first opening has an included angle with a net-deployment stretching direction of the masks.

25. The mask group according to claim 24, wherein a connecting line between a center of the orthographic projection of the outer contour of the third opening on the first mask and the center of the outer contour of the first opening has an included angle with a vapor-deposition scanning direction.

26. The mask group according to claim 25, wherein the orthographic projection of the outer contour of the second opening on the first mask and the orthographic projection of the outer contour of the third opening on the first mask are tangent to the outer contour of the first opening, and the orthographic projection of the outer contour of the second opening on the first mask and the orthographic projection of the outer contour of the third opening on the first mask are tangent to each other; or
wherein the included angle between the connecting line between the center of the orthographic projection of the outer contour of the second opening on the first mask and the center of the outer contour of the first opening and the net-deployment stretching direction of the masks is greater than 0° and less than or equal to 30°; or
wherein the included angle between the connecting line between the center of the orthographic projection of the outer contour of the third opening on the first mask and the center of the outer contour of the first opening and the vapor-deposition scanning direction is greater than 0° and less than or equal to 30°.

27. (canceled)

28. (canceled)
